(19) United States
(12) Patent Application Publication
(10) Pub. No.: US 2026/0255867 A1
(43) Pub. Date: Aug. 27, 2026

(54) COPOLYMER AND THIN FILM TRANSISTOR AND ELECTRONIC DEVICE

(71) Applicant: Samsung Electronics Co., Ltd., Suwon-si (KR)

(72) Inventors: Hyung Jun KIM, Suwon-si (KR); Hyun Bum KANG, Suwon-si (KR); Kyunghun KIM, Suwon-si (KR); Gae Hwang LEE, Suwon-si (KR); Bang Lin LEE, Suwon-si (KR)

(73) Assignee: Samsung Electronics Co., Ltd., Suwon-si (KR)

(21) Appl. No.: 19/322,051

(22) Filed: Sep. 8, 2025

(30) Foreign Application Priority Data
Sep. 12, 2024 (KR) 10-2024-0124696

(51) Int. Cl. H10K 85/10; H10K 10/46

(52) U.S. Cl. CPC H10K 85/151; H10K 85/113; H10K 10/484

(57) ABSTRACT

Described are a copolymer including a first repeating unit represented by Chemical Formula 1 and a second repeating unit represented by Chemical Formula 2, a thin film transistor including the same, and an electronic device including same.

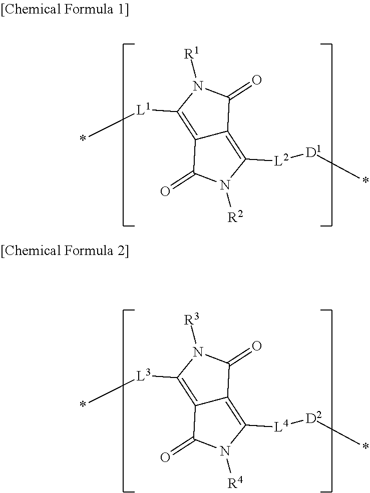

In Chemical Formula 1 or 2, D¹, D², L¹ to L⁴, and R¹ to R⁴ are the same as described in the detailed description.

### CROSS-REFERENCE TO RELATED APPLICATION

This application claims priority to and the benefit of Korean Patent Application No. 10-2024-0124696 filed with the Korean Intellectual Property Office on Sep. 12, 2024, the entire contents of which are incorporated herein by reference.

### BACKGROUND

### 1. Field

Example embodiments relate to copolymers, thin film transistors, and electronic devices.

### 2. Description of the Related Art

Flat panel displays such as liquid crystal display (LCD) displays or organic light emitting diode (OLED) displays, include a thin film transistor (TFT) that is a three-terminal element as a switching device or a driving device. The thin film transistor includes a gate electrode, a source electrode, and a drain electrode, and a semiconductor for controlling the current between a source electrode and a drain electrode by a gate voltage.

The organic thin film transistor (OTFT) includes an organic semiconductor such as a low molecular or polymer instead of an inorganic semiconductor such as silicon (Si) as a semiconductor. The OTFT may be made into fibers or films due to the nature of organic materials, and thus it is attracting attention as a core element of flexible display devices or stretchable display devices.

### SUMMARY

Some example embodiments provide a copolymer that is applicable to solution processes and may provide improved electrical characteristics.

Some example embodiments provide a thin film transistor including the copolymer.

Some example embodiments provide an electronic device including the copolymer or the thin film transistor.

According to some example embodiments, a copolymer may include a first repeating unit represented by Chemical Formula 1 and a second repeating unit represented by Chemical Formula 2.

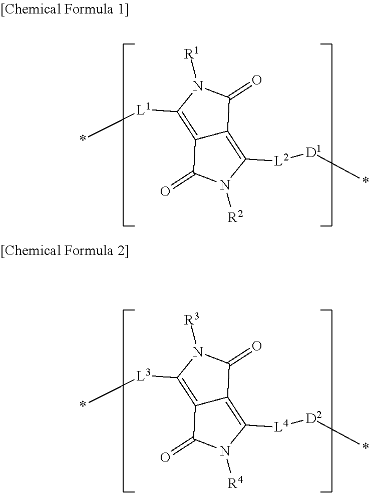

In in Chemical Formula 1 and Chemical Formula 2,
D¹ and D² may each independently be an electron donating moiety,
L¹ to L⁴ may each independently be a single bond, a substituted or unsubstituted C1 to C20 alkylene group, a substituted or unsubstituted C6 to C30 arylene group, a substituted or unsubstituted C3 to C30 divalent heterocyclic group, a fused ring thereof, or any combination thereof,
R¹ and R² may each independently be a substituted or unsubstituted C5 to C50 branched alkyl group,
one of R³ or R⁴ may be a substituted or unsubstituted C1 to C50 linear alkyl group, and another one of R³ or R⁴ may be a substituted or unsubstituted C5 to C50 branched alkyl group, and
* may be a linking point.

In Chemical Formula 1 and Chemical Formula 2, D¹ and D² may each independently include a substituted or unsubstituted C6 to C30 arylene group; a substituted or unsubstituted C3 to C30 divalent heterocyclic group including at least one selected from O, S, Se, Te, or Si; a fused ring thereof; or any combination thereof.

In Chemical Formula 1 and Chemical Formula 2, D¹ and D² may each independently be one or more substituted or unsubstituted phenylene groups; one or more substituted or unsubstituted naphthylene groups; one or more substituted or unsubstituted anthracenylene groups; one or more substituted or unsubstituted phenanthrenylene groups; one or more substituted or unsubstituted C3 to C30 heterocyclic groups including at least one selected from O, S, Se, Te, or Si; a fused ring of one or more substituted or unsubstituted C3 to C30 heterocyclic groups including at least one selected from O, S, Se, Te, or Si; a fused ring of one or more substituted or unsubstituted C3 to C30 heterocyclic groups and one or more substituted or unsubstituted phenylene group; a fused ring of one or more substituted or unsubstituted C3 to C30 heterocyclic groups and one or more substituted or unsubstituted naphthylene groups; a fused ring of one or more substituted or unsubstituted C3 to C30 heterocyclic groups and one or more substituted or unsubstituted anthracenylene groups; a fused ring of one or more substituted or unsubstituted C3 to C30 heterocyclic groups and one or more substituted or unsubstituted phenanthrenylene groups; or any combination thereof.

In Chemical Formula 1 and Chemical Formula 2, D¹ and D² may each independently include one of groups 1-1 to 1-13 listed in Group 1.

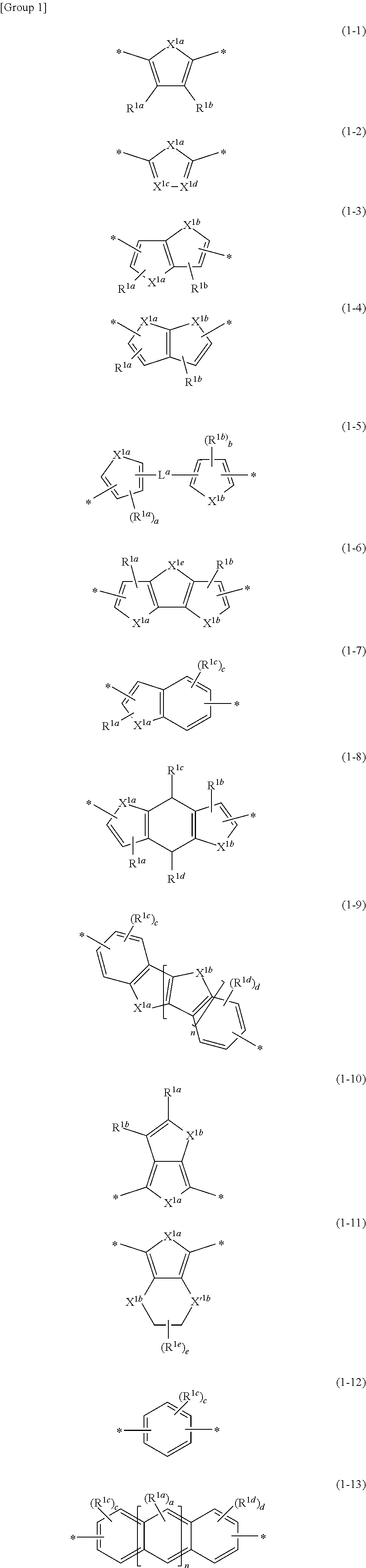

In Group 1,

X^{1a}, X^{1b}, and X′^{1b} may each independently be O, S, Se, Te, or Si,

X^{1c} and X^{1d} may each independently be N, CR^{x}, or SiR^{y},

X^{1e} may be O, S, Se, Te, NR^{v}, CR^{w}R^{x}, or SiR^{y}R^{z},

R^{1a}, R^{1b}, R^{1c}, R^{1d}, R^{1e}, R^{x}, R^{y}, R^{v}, R^{w}, and R^{z} may each independently be hydrogen, a substituted or unsubstituted C1 to C30 alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C3 to C30 cycloalkenyl group, a substituted or unsubstituted C1 to C30 alkoxy group, a substituted or unsubstituted C3 to C30 cycloheteroalkyl group, a substituted or unsubstituted C3 to C30 cycloheteroalkenyl group, a substituted or unsubstituted C6 to C30 aryl group, a substituted or unsubstituted C3 to C30 heterocyclic group, a halogen, or a cyano group,

L^{a} may be a single bond or a substituted or unsubstituted C2 to C10 alkenylene group,

a and b may each independently be 1 or 2,

c and d may each independently be an integer of 1 to 3,

e may be an integer of 1 to 4,

n may be 0, 1, or 2, and

* may be a linking point with Chemical Formula 1 or Chemical Formula 2.

In Chemical Formula 1 and Chemical Formula 2, L¹ to L⁴ may each independently include a single bond; a substituted or unsubstituted C6 to C30 arylene group; a substituted or unsubstituted C3 to C30 divalent heterocyclic group including at least one selected from N, O, S, Se, Te, or Si; or any combination thereof, L¹ and L² may each be different from D¹, and L³ and L⁴ may each be different from D².

In Chemical Formula 1 and Chemical Formula 2, L¹ to L⁴ may each independently include a single bond; a substituted or unsubstituted phenylene group; a substituted or unsubstituted naphthylene group; a substituted or unsubstituted C3 to C30 divalent heterocyclic group including at least one selected from O, S, Se, Te, or Si; or any combination thereof.

In Chemical Formula 1 and Chemical Formula 2, L¹ to L⁴ may each independently include one of groups 2-1 to 2-8 listed in Group 2.

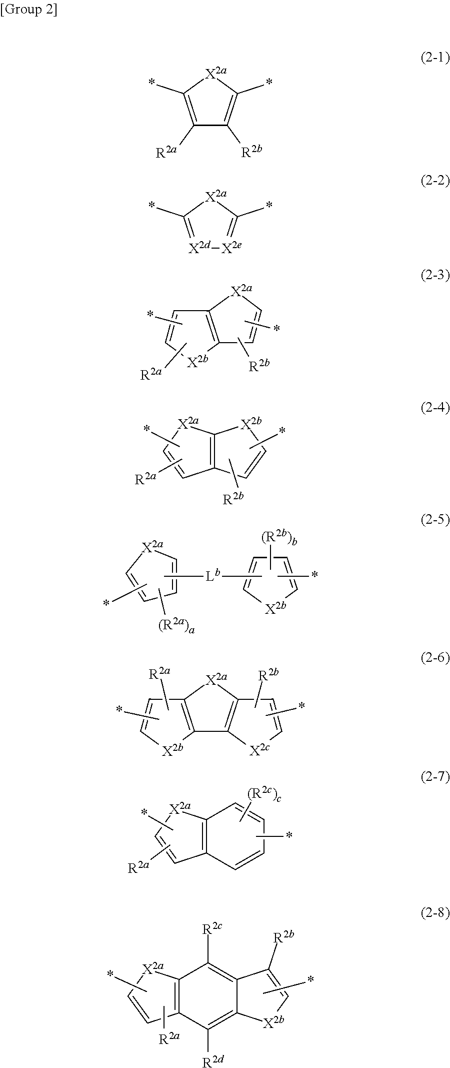

In Group 2,

X^{2a} to X^{2c} may each independently be O, S, Se, or Te,

X^{2d} and X^{2e} may each independently be N, CR^{x}, or SiR^{y},

R^{2a}, R^{2b}, R^{2c}, R^{2d}, R^{x}, and R^{y} may each independently be hydrogen, a substituted or unsubstituted C1 to C30 alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C3 to C30 cycloalkenyl group, a substituted or unsubstituted C1 to C30 alkoxy group, a substituted or unsubstituted C3 to C30 cycloheteroalkyl group, a substituted or unsubstituted C3 to C30 cycloheteroalkenyl group, a substituted or unsubstituted C6 to C30 aryl group, a substituted or unsubstituted C3 to C30 heterocyclic group, a halogen, or a cyano group,

L^{b} may be a single bond or a substituted or unsubstituted C2 to C10 alkenylene group,

a and b may each independently be 1 or 2,

c may be an integer of 1 to 3, and

* may be a linking point with Chemical Formula 1 or Chemical Formula 2.

In Chemical Formula 1 and Chemical Formula 2, R³ may be a substituted or unsubstituted C5 to C50 branched alkyl group, and R¹ to R³ may each independently be represented by Chemical Formula A.

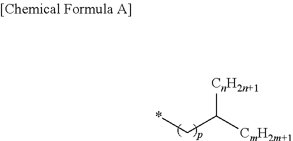

In Chemical Formula A,

n, m, and p may each independently be an integer of 1 to 30, and * may be a linking point with Chemical Formula 1 or Chemical Formula 2, wherein a sum of n, m, and p is less than or equal to 50.

In Chemical Formula 2, R⁴ may be a substituted or unsubstituted C1 to C50 linear alkyl group, and R⁴ may be represented by Chemical Formula B.

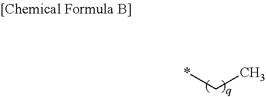

In Chemical Formula B, q may be an integer of 0 to 49, and * may be a linking point with Chemical Formula 2.

In Chemical Formula 1 and Chemical Formula 2, R¹ to R³ may be a same C5 to C50 branched alkyl group, and R⁴ may be a substituted or unsubstituted C1 to C50 linear alkyl group.

The first repeating unit and the second repeating unit may be randomly arranged in the copolymer such that the copolymer includes a random arrangement of a first repeating unit quantity of units of the first repeating unit and a second repeating unit quantity of units of the second repeating unit, and the second repeating unit quantity may be smaller than the first repeating unit quantity in the copolymer.

The second repeating unit may be included, in the copolymer, in an amount of about 5 mol % to about 30 mol % based on a total amount of the first repeating unit and the second repeating unit in the copolymer.

According to some example embodiments, a copolymer includes a random arrangement of a first repeating unit quantity of a first repeating unit (e.g., a first repeating unit quantity of units of the first repeating unit) and a second repeating unit quantity of a second repeating unit (e.g., a second repeating unit quantity of units of the second repeating unit), the first repeating unit including a first electron accepting moiety and a first electron donating moiety, the first electron accepting moiety having a symmetric structure, the second repeating unit including a second electron accepting moiety and a second electron donating moiety, the second electron accepting moiety having an asymmetric structure, and the second repeating unit quantity may be smaller than the first repeating unit quantity in the copolymer.

The second electron accepting moiety may have a structure in which a main chain of a C6 to C30 aromatic ring or a C3 to C30 heterocyclic ring including at least one of nitrogen, a carbonyl group, a halogen, or a cyano group is substituted with a substituted or unsubstituted C1 to C50 linear alkyl group and a substituted or unsubstituted C5 to C50 branched alkyl group.

The first electron accepting moiety may have a structure in which a main chain of a C6 to C30 aromatic ring or a C3 to C30 heterocyclic ring including at least one of nitrogen, a carbonyl group, a halogen, or a cyano group is substituted with two substituted or unsubstituted C5 to C50 branched alkyl groups positioned symmetrically to each other.

The first electron donating moiety and the second electron donating moiety may each independently be a substituted or unsubstituted C6 to C30 arylene group; a substituted or unsubstituted C3 to C30 divalent heterocyclic group including at least one selected from O, S, Se, Te, or Si; a fused ring thereof; or any combination thereof.

The second repeating unit may be included in the copolymer in an amount of about 5 mol % to 30 mol % based on a total amount of the first repeating unit and the second repeating unit in the copolymer.

According to some example embodiments, a thin film transistor includes a gate electrode, an organic semiconductor overlapped with the gate electrode and including the copolymer, and a source electrode and a drain electrode electrically connected to the organic semiconductor.

According to some example embodiments, an electronic device including the copolymer or the thin film transistor is provided.

A uniform polymer film with improved electrical characteristics may be provided by simultaneously increasing the solubility and crystallinity of the polymer.

### BRIEF DESCRIPTION OF THE DRAWINGS

FIGS. 1, 2, and 3 are cross-sectional views each showing thin film transistors according to some example embodiments;

FIG. 4 illustrates a block diagram showing an electronic device according to some example embodiments; and

FIG. 5 is a graph showing the light absorption characteristics of the copolymer according to Synthesis Example 7 and the polymer according to Comparative Synthesis Example 1.

### DETAILED DESCRIPTION

Some example embodiments will hereinafter be described in detail, and may be easily performed by those who have common knowledge in the related art. However, the inventive concepts may be embodied in many different forms and is not to be construed as limited to the example embodiments set forth herein.

In the drawings, the thickness of layers, films, panels, regions, etc., are exaggerated for clarity.

It will be understood that when an element such as a layer, film, region, or substrate is referred to as being “on” another element, it may be directly on the other element or intervening elements may also be present. In contrast, when an element is referred to as being “directly on” another element, there are no intervening elements present.

As used herein, when a definition is not otherwise provided, “substituted” refers to replacement of hydrogen of a compound by a substituent selected from a halogen, a hydroxy group, a nitro group, a cyano group, an amino group, an azido group, an amidino group, a hydrazino group, a hydrazono group, a carbonyl group, a carbamyl group, a thiol group, an ester group, a carboxyl group or a salt thereof, a sulfonic acid group or a salt thereof, a phosphoric acid group or a salt thereof, a C1 to C30 alkyl group, a C2 to C30 alkenyl group, a C2 to C30 alkynyl group, a C6 to C30 aryl group, a C7 to C30 arylalkyl group, a C1 to C30 alkoxy group, a C1 to C20 heteroalkyl group, a C3 to C20 heterocyclic group, a C3 to C20 heteroarylalkyl group, a C3 to C30 cycloalkyl group, a C3 to C15 cycloalkenyl group, a C6 to C15 cycloalkynyl group, a C3 to C30 heterocycloalkyl group, and any combination thereof.

As used herein, when a definition is not otherwise provided, “hetero” refers to one including 1 to 4 heteroatoms selected from N, O, S, Se, Te, Si, and P.

As used herein, when a definition is not otherwise provided, “alkyl group” is a linear or branched saturated monovalent hydrocarbon group (e.g., a methyl group, an ethyl group, a propyl group, an isobutyl group, a sec-butyl group, a tert-butyl group, a pentyl group, an iso-amyl group, a hexyl group, and the like).

As used herein, when a definition is not otherwise provided, “alkoxy group” refers to an alkyl group that is linked via an oxygen, e.g., a methoxy group, an ethoxy group, and a sec-butyloxy group.

As used herein, when a definition is not otherwise provided, “aryl group” refers to a monovalent functional group formed by the removal of one hydrogen atom from one or more rings of an arene, e.g., phenyl or naphthyl. The arene refers to a hydrocarbon having an aromatic ring, and includes monocyclic and polycyclic hydrocarbons wherein the additional ring(s) of the polycyclic hydrocarbon may be aromatic or nonaromatic.

As used herein, when a definition is not otherwise provided, “heterocyclic group” includes at least one heteroatom such as N, O, S, Se, Te, Si, or P in a ring such as an aryl group, a cycloalkyl group, a fused ring thereof, or any combination thereof, and the remaining carbon. When the heterocyclic group is a fused ring, a heteroatom may be included in the entire heterocyclic group or at least one of the rings.

As used herein, when a definition is not otherwise provided, “aromatic ring” refers to a functional group in which all atoms in the cyclic functional group have a p-orbital, and wherein these p-orbitals are conjugated. For example, the aromatic ring may be a C6 to C30 aryl group.

The use of the term “the” and similar demonstratives may correspond to both the singular and the plural. Operations constituting methods may be performed in any suitable order unless otherwise indicated herein or otherwise clearly contradicted by context, and are not necessarily limited to the stated order.

The use of all illustrations or illustrative terms in some example embodiments is simply to describe the technical ideas in detail, and the scope of the present inventive concepts is not limited by the illustrations or illustrative terms unless they are limited by claims.

Regardless of whether elements and/or properties thereof are modified as “substantially,” it will be understood that these elements and/or properties thereof should be construed as including a manufacturing or operational tolerance (e.g., ±10%) around the stated elements and/or properties thereof.

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

As described herein, when an operation is described to be performed, or an effect such as a structure is described to be established “by” or “through” performing additional operations, it will be understood that the operation may be performed and/or the effect/structure may be established “based on” the additional operations, which may include performing said additional operations alone or in combination with other further additional operations.

Hereinafter, a copolymer according to some example embodiments is described.

A copolymer according to some example embodiments may be a semiconducting polymer and may be composed of a plurality of repeating units having different properties.

The copolymer may include a first repeating unit and a second repeating unit (e.g., the copolymer may include a first repeating unit quantity of units of the first repeating unit and a second repeating unit quantity of units of the second repeating unit). The first repeating unit and the second repeating unit may each be a semiconducting repeating unit having an electron donating moiety and an electron accepting moiety, respectively, and may each exhibit semiconductor characteristics through an interaction between the electron donating moiety and the electron accepting moiety, respectively. The electron donating moiety and the electron accepting moiety in each first repeating unit and/or each second repeating unit may be directly linked or indirectly linked through a linking group.

The first repeating unit and the second repeating unit may include the same or different electron donating moieties having electron donating characteristics, for example, a substituted or unsubstituted C6 to C30 arylene group; a substituted or unsubstituted C3 to C30 divalent heterocyclic group comprising at least one selected from O, S, Se, Te, or Si; a fused ring thereof; or any combination thereof.

For example, the electron donating moiety may be one or more substituted or unsubstituted phenylene groups; one or more substituted or unsubstituted naphthylene groups; one or more substituted or unsubstituted anthracenylene groups; one or more substituted or unsubstituted phenanthrenylene groups; one or more substituted or unsubstituted C3 to C30 heterocyclic groups including at least one selected from O, S, Se, Te, or Si; a fused ring of one or more substituted or unsubstituted C3 to C30 heterocyclic groups including at least one selected from O, S, Se, Te, or Si; a fused ring of one or more substituted or unsubstituted C3 to C30 heterocyclic groups and one or more substituted or unsubstituted phenylene group; a fused ring of one or more substituted or unsubstituted C3 to C30 heterocyclic groups and one or more substituted or unsubstituted naphthylene groups; a fused ring of one or more substituted or unsubstituted C3 to C30 heterocyclic groups and one or more substituted or unsubstituted anthracenylene groups; a fused ring of one or more substituted or unsubstituted C3 to C30 heterocyclic groups and one or more substituted or unsubstituted phenanthrenylene groups; or any combination thereof.

The electron donating moiety included in the first repeating unit and the second repeating unit may be, for example, one of the groups listed in Group 1 (e.g., one of groups 1-1 to 1-13 listed in Group 1), but is not limited thereto.

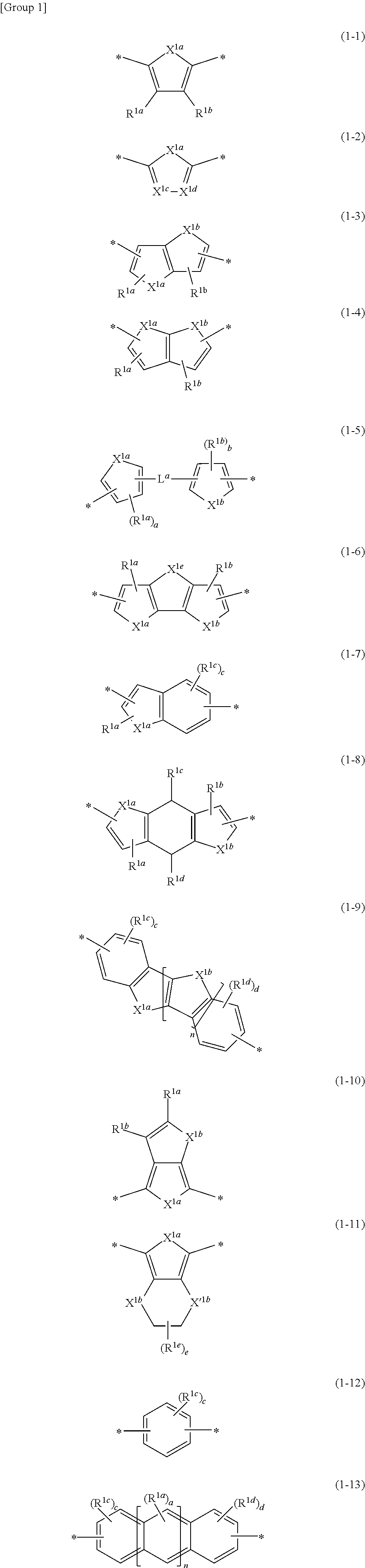

In Group 1,

X^{1a}, X^{1b}, and X′^{1b} may each independently be O, S, Se, Te, or Si,

X^{1c} and X^{1d} may each independently be N, CR^{x}, or SiR^{y},

X^{1e} may be O, S, Se, Te, NR^{v}, CR^{w}R^{x}, or SiR^{y}R^{z},

R^{1a}, R^{1b}, R^{1c}, R^{1d}, R^{1e}, R^{x}, R^{y}, R^{v}, R^{w}, and R^{z} may each independently be hydrogen, a substituted or unsubstituted C1 to C30 alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C3 to C30 cycloalkenyl group, a substituted or unsubstituted C1 to C30 alkoxy group, a substituted or unsubstituted C3 to C30 cycloheteroalkyl group, a substituted or unsubstituted C3 to C30 cycloheteroalkenyl group, a substituted or unsubstituted C6 to C30 aryl group, a substituted or unsubstituted C3 to C30 heterocyclic group, a halogen, or a cyano group,

L^{a} may be a single bond or a substituted or unsubstituted C2 to C10 alkenylene group,

a and b may each independently be 1 or 2,

c and d may each independently be an integer of 1 to 3,

e may be an integer of 1 to 4,

n may be 0, 1, or 2, and

* may be a linking point with Chemical Formula 1 or 2.

The first repeating unit and the second repeating unit may each include an electron accepting moiety having electron accepting characteristics. The electron accepting moiety included in the first repeating unit and the electron accepting moiety included in the second repeating unit may be structurally different. For example, one of the electron accepting moiety included in the first repeating unit and the electron accepting moiety included in the second repeating unit may have a symmetric structure, and the other of the electron accepting moiety included in the first repeating unit and the electron accepting moiety included in the second repeating unit may have an asymmetric structure.

For example, the electron accepting moiety included in the first repeating unit and the electron accepting moiety included in the second repeating unit may have the same main chain structure, and may have a planar typed main chain structure including, for example, a C6 to C30 aromatic ring or a C3 to C30 heterocyclic ring including at least one of nitrogen, a carbonyl group, a halogen, or a cyano group. For example, the electron accepting moiety included in the first repeating unit and the electron accepting moiety included in the second repeating unit may commonly include a substituted or unsubstituted diketopyrrolopyrrole moiety.

For example, the electron accepting moiety included in the first repeating unit (such electron accepting moiety also referred to herein interchangeably as a first electron accepting moiety) may have a symmetric structure, and the electron accepting moiety included in the second repeating unit may have an asymmetric structure. The symmetric/asymmetric structure of the electron accepting moiety may be determined depending on the side chain bonded to the main chain.

The electron accepting moiety included in the first repeating unit may include multiple side chain groups, for example, multiple bulky alkyl groups arranged symmetrically. For example, the electron accepting moiety included in the first repeating unit may have two substituents substituted symmetrically to each other on a C6 to C30 aromatic ring or a C3 to C30 heterocyclic ring including at least one of nitrogen, a carbonyl group, a halogen, or a cyano group, and for example, the two substituents may each be a bulky branched alkyl group and may each be a substituted or unsubstituted C5 to C50 branched alkyl group. For example, the electron accepting moiety included in the first repeating unit (e.g., the first electron accepting moiety) may have a structure in which a main chain of a C6 to C30 aromatic ring or a C3 to C30 heterocyclic ring including at least one of nitrogen, a carbonyl group, a halogen, or a cyano group is substituted with two substituted or unsubstituted C5 to C50 branched alkyl groups positioned symmetrically to each other.

The electron accepting moiety included in the second repeating unit (such electron accepting moiety also referred to herein interchangeably as a second electron accepting moiety) may include multiple side chain groups, and for example, one side may include a bulky alkyl group and the other side may include an elongated alkyl group in one direction, thereby forming an asymmetric structure. For example, the electron accepting moiety included in the second repeating unit may be substituted on one side of a C6 to C30 aromatic ring or a C3 to C30 heterocyclic ring including at least one of nitrogen, a carbonyl group, a halogen, or a cyano group with a substituted or unsubstituted C5 to C50 branched alkyl group, and substituted on the other side with a substituted or unsubstituted C1 to C50 linear alkyl group. For example, the electron accepting moiety in the second repeating unit (e.g., the second electron accepting moiety) may have a structure in which a main chain of a C6 to C30 aromatic ring or a C3 to C30 heterocyclic ring including at least one of nitrogen, a carbonyl group, a halogen, or a cyano group is substituted with a substituted or unsubstituted C1 to C50 linear alkyl group and a substituted or unsubstituted C5 to C50 branched alkyl group. For example, the first electron donating moiety in the first repeating unit and the second electron donating moiety in the second repeating unit may each independently comprise a substituted or unsubstituted C6 to C30 arylene group; a substituted or unsubstituted C3 to C30 divalent heterocyclic group including at least one selected from O, S, Se, Te, or Si; a fused ring thereof; or any combination thereof.

In some example embodiments, the copolymer may include, for example in addition to the first repeating unit, a repeating unit (e.g., the second repeating unit) including an electron accepting moiety having an asymmetric structure in which one side of the planar typed (also referred to herein as simply “planar”) main chain structure is substituted with a bulky branched alkyl group and the other side of the planar typed main chain structure is substituted with a linear alkyl group extending in one direction, and thus may simultaneously satisfy improved electrical characteristics and improved solubility of the copolymer.

For example, polymers (homopolymers) having a planar typed main chain structure substituted with branched alkyl groups (e.g., a polymer including the first repeating unit but not including the second repeating unit) may have high solubility in organic solvents for solution processes, but may have low crystallinity and thus relatively low charge mobility. In order to provide improved charge mobility relative to such a polymer, the copolymer may be designed and/or configured to further include, in addition to the first repeating unit, a second repeating unit capable of increasing charge mobility of the copolymer relative to a polymer not including the second repeating unit (e.g., a homopolymer including the first repeating unit but not the second repeating unit), and an asymmetric electron accepting moiety having both a long linear alkyl group extending in one direction and a bulky branched alkyl group may be included in the second repeating unit, thereby ensuring that the copolymer is configured to have, relative to a polymer not including both the first and second repeating units (e.g., a homopolymer including the first repeating unit but not the second repeating unit), increased crystallinity (and thus improved charge mobility) without compromising solubility of the copolymer. As a result, the copolymer may have a solubility that is equal to or greater than that of the polymer not including both the first and second repeating units while having increased crystallinity (and thus improved charge mobility) relative to such a polymer. Accordingly, a thin film, copolymer film, and/or organic semiconductor may be formed to include the copolymer, and such a thin film, copolymer film, and/or organic semiconductor, and device such as a thin film transistor including same, may exhibit improved charge mobility and/or improved performance based on including the copolymer. In some example embodiments, the copolymer may be used (e.g., together with a solvent) to form a copolymer film (also referred to herein as a thin film) that may be provided as an organic semiconductor, an active layer, charge transport layer, or any combination thereof, in an electronic device, for example a thin film transistor and/or an electronic device including same, and the organic semiconductor, active layer, charge transport layer, etc. and any device including same may exhibit improved performance based on improved charge mobility exhibited by the copolymer film due to including the copolymer.

If the second repeating unit includes a symmetric electron accepting moiety substituted with two linear alkyl groups instead of the asymmetric electron accepting moiety, the solubility of the polymer having such a second repeating unit in an organic solvent may become very low and the crystallinity may become excessively high, so that precipitation may occur during polymerization and it may be difficult to form a uniform film. In contrast, an electron accepting moiety of a second repeating unit in a polymer or copolymer having a linear alkyl group extending in one direction and a bulky branched alkyl group on opposite side chains, as described above, may effectively improve the charge mobility of the polymer or copolymer, and thus improve the charge mobility and performance of a thin film, copolymer film, organic semiconductor, electronic device, and/or thin film transistor including same, by inducing π-π stacking to increase inter-chain interaction while ensuring solubility of the polymer or copolymer including such a second repeating unit in an organic solvent.

The copolymer including the first repeating units and second repeating units may simultaneously satisfy solubility and crystallinity (e.g., may exhibit increased crystallinity and thus exhibit increased charge mobility without compromising solubility and/or may have both increased crystallinity and charge mobility and equal or increased solubility in relation to a polymer not including the second repeating unit), and thus may be formed into a uniform copolymer film having high charge mobility (e.g., hole mobility) and may be included in a thin film transistor and/or electronic device having improved charge mobility and/or improved performance based on including a copolymer film that includes the copolymer.

The first repeating unit and the second repeating unit may be randomly arranged in the copolymer, and the second repeating unit may be included, in the copolymer, in a smaller amount than the first repeating unit. For example, the copolymer may include a random arrangement of a first repeating unit quantity of units of the first repeating unit and a second repeating unit quantity of units of the second repeating unit, where the second repeating unit quantity may be smaller than the first repeating unit quantity. Accordingly, a copolymer having an effective balance of solubility and crystallinity as described above may be provided, which may configure the copolymer to be used to form a thin film, copolymer film, and/or organic semiconductor having an improved charge mobility and thereby enabling a thin film transistor and/or electronic device including same to have improved performance.

For example, the second repeating unit (e.g., a second repeating unit quantity of units thereof) may be included, in the copolymer, in an amount of less than or equal to about 30 mol %, and within this range, for example, about 5 mol % to about 30 mol %, about 7 mol % to about 30 mol %, about 10 mol % to about 30 mol %, about 5 mol % to about 28 mol %, about 7 mol % to about 28 mol %, about 10 mol % to about 28 mol %, about 5 mol % to about 25 mol %, about 7 mol % to about 25 mol %, about 10 mol % to about 25 mol %, or about 15 mol % to about 25 mol % based on a total amount of the first repeating unit and the second repeating unit (e.g., a total amount of the units thereof) in the copolymer.

In some example embodiments, the copolymer may include a first repeating unit represented by Chemical Formula 1 and a second repeating unit represented by Chemical Formula 2.

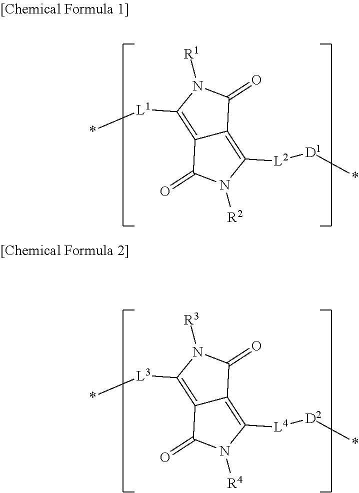

In Chemical Formula 1 and Chemical Formula 2,

D¹ and D² may each independently be an electron donating moiety,

L¹ to L⁴ may each independently be a single bond, a substituted or unsubstituted C1 to C20 alkylene group, a substituted or unsubstituted C6 to C30 arylene group, a substituted or unsubstituted C3 to C30 divalent heterocyclic group, a fused ring thereof, or any combination thereof,

R¹ and R² may each independently be a substituted or unsubstituted C5 to C50 branched alkyl group,

one of R³ or R⁴ may be a substituted or unsubstituted C1 to C50 linear alkyl group, and the other (another) of R³ or R⁴ may be a substituted or unsubstituted C5 to C50 branched alkyl group, and

* may be a linking point, for example a with an atom of the copolymer (e.g., a linking point with a first repeating unit represented by Chemical Formula 1 or a second repeating unit represented by Chemical Formula 2).

For example, in Chemical Formula 1 and Chemical Formula 2, D¹ and D² may each independently be a substituted or unsubstituted C6 to C30 arylene group; a substituted or unsubstituted C3 to C30 divalent heterocyclic group including at least one selected from O, S, Se, Te, or Si; a fused ring thereof; or any combination thereof.

For example, in Chemical Formula 1 and Chemical Formula 2, D¹ and D² may each independently be one or more substituted or unsubstituted phenylene groups; one or more substituted or unsubstituted naphthylene groups; one or more substituted or unsubstituted anthracenylene groups; one or more substituted or unsubstituted phenanthrenylene groups; one or more substituted or unsubstituted C3 to C30 heterocyclic groups including at least one selected from O, S, Se, Te, or Si; a fused ring of one or more substituted or unsubstituted C3 to C30 heterocyclic groups including at least one selected from O, S, Se, Te, or Si; a fused ring of one or more substituted or unsubstituted C3 to C30 heterocyclic groups and one or more substituted or unsubstituted phenylene group; a fused ring of one or more substituted or unsubstituted C3 to C30 heterocyclic groups and one or more substituted or unsubstituted naphthylene groups; a fused ring of one or more substituted or unsubstituted C3 to C30 heterocyclic groups and one or more substituted or unsubstituted anthracenylene groups; a fused ring of one or more substituted or unsubstituted C3 to C30 heterocyclic groups and one or more substituted or unsubstituted phenanthrenylene groups; or any combination thereof. For example, in Chemical Formula 1 and Chemical Formula 2, D¹ and D² may each be independently selected from the substituted or unsubstituted divalent ring groups listed in the Group 1 described above (e.g., D¹ and D² may each independently comprise one of groups 1-1 to 1-13 listed in Group 1), but example embodiments are not limited thereto.

For example, in Chemical Formula 1 and Chemical Formula 2, L¹ to L⁴ may each be a linking group, and may each independently include a single bond; a substituted or unsubstituted C6 to C30 arylene group; a substituted or unsubstituted C3 to C30 divalent heterocyclic group including at least one selected from N, O, S, Se, Te, or Si; or any combination thereof. Each linker may be different from the electron donating moiety in the repeating unit. for example, L¹ and L² may each be different from D¹, and L³ and L⁴ may each be different from D².

For example, in Chemical Formula 1 and Chemical Formula 2, L¹ to L⁴ may each independently include a single bond; a substituted or unsubstituted phenylene group; a substituted or unsubstituted naphthylene group; a substituted or unsubstituted C3 to C30 heterocyclic group including at least one selected from O, S, Se, Te, or Si; or any combination thereof.

For example, in Chemical Formula 1 and Chemical Formula 2, L¹ to L⁴ may each independently include one of the groups listed in Group 2 (e.g., one of groups 2-1 to 2-8 listed in Group 2), but are not limited thereto.

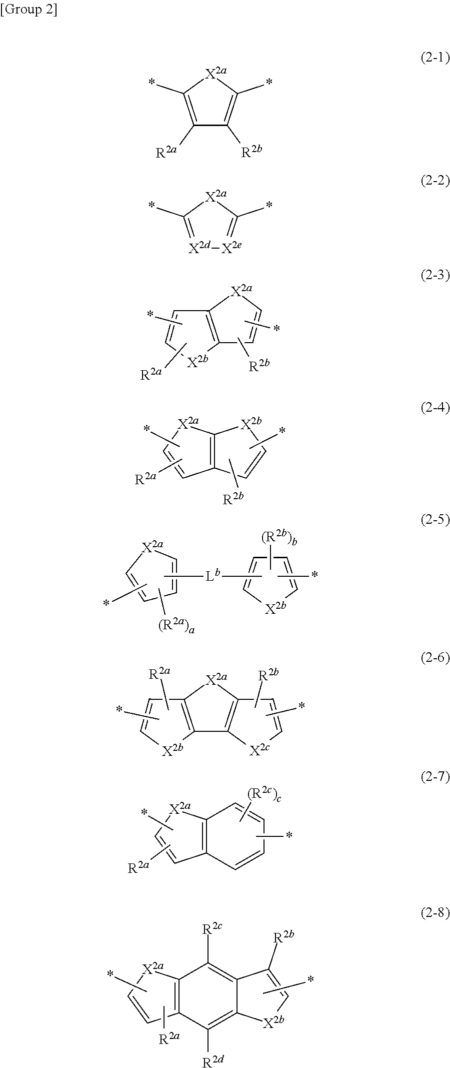

In Group 2,

X^{2a} to X^{2c}may each independently be O, S, Se, or Te,

X^{2d} and X^{2e} may each independently be N, CR^{x}, or SiR^{y},

R^{2a}, R^{2b}, R^{2c}, R^{2d}, R^{x}, and R^{y} may each independently be hydrogen, a substituted or unsubstituted C1 to C30 alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C3 to C30 cycloalkenyl group, a substituted or unsubstituted C1 to C30 alkoxy group, a substituted or unsubstituted C3 to C30 cycloheteroalkyl group, a substituted or unsubstituted C3 to C30 cycloheteroalkenyl group, a substituted or unsubstituted C6 to C30 aryl group, a substituted or unsubstituted C3 to C30 heterocyclic group, a halogen, or a cyano group,

L^{b} may be a single bond or a substituted or unsubstituted C2 to C10 alkenylene group,

a and b may each independently be 1 or 2,

c may be an integer of 1 to 3, and

* may be a linking point with Chemical Formula 1 or Chemical Formula 2.

For example, L¹ may be the same as L^{2,} and L³ may be same as L⁴.

For example, L¹ and L² may be different from L³ and/or L⁴.

For example, R¹ may be the same as R², and thus R¹ and R² may form an electron accepting moiety of symmetric structure.

For example, R³ may be a substituted or unsubstituted C5 to C50 branched alkyl group, and R⁴ may be a substituted or unsubstituted C1 to C50 linear chain alkyl group. Accordingly, R¹ to R³ may be the same or different substituted or unsubstituted C5 to C50 branched alkyl groups.

For example, in Chemical Formula 1 and Chemical Formula 2, R¹ to R³ may each be independently represented by Chemical Formula A.

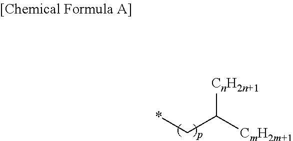

In Chemical Formula A, n, m, and p may each independently be an integer of 1 to 30. In some example embodiments, a sum of n, m, and p may be less than or equal to 50.

For example, in Chemical Formula 1 and Chemical Formula 2, R¹ to R³ may be the same C5 to C50 branched alkyl group.

For example, in Chemical Formula 2, R⁴ may be represented by Chemical Formula B.

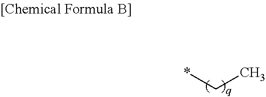

In Chemical Formula B, q may be an integer of 0 to 49.

For example, q in Chemical Formula B may be equal to or greater than p in Chemical Formula A.

For example, in Chemical Formula 2, R⁴ may be a substituted or unsubstituted C1 to C50 linear alkyl group.

In Chemical Formula A or B, * may be a linking point with the main chain. For example, in Chemical Formula A, * may be a linking point with Chemical Formula 1 or Chemical Formula 2. For example, in Chemical Formula B, * may be a linking point with Chemical Formula 2.

As described above, the first repeating unit and the second repeating unit (e.g., respective units thereof) may be randomly arranged in the copolymer, and the second repeating unit (e.g., respective units thereof) may be included, in the copolymer, in a smaller amount than the first repeating unit (e.g., respective units thereof). For example, the copolymer may include a first repeating unit quantity of units of the first repeating unit and a second repeating unit quantity of units of the second repeating unit (e.g., a random arrangement thereof), and the second repeating unit quantity may be smaller than the first repeating unit quantity. For example, the second repeating unit (e.g., respective units thereof) may be included, in the copolymer, in an amount of less than or equal to about 30 mol %, and within the above range, for example, about 5 mol % to about 30 mol %, about 7 mol % to about 30 mol %, about 10 mol % to about 30 mol %, about 5 mol % to about 28 mol %, about 7 mol % to about 28 mol %, about 10 mol % to about 28 mol %, about 5 mol % to about 25 mol %, about 7 mol % to about 25 mol %, about 10 mol % to about 25 mol %, or about 15 mol % to about 25 mol % based on a total amount of the first repeating unit and the second repeating unit (e.g., the total amounts of the units thereof) in the copolymer.

The copolymer may be obtained by copolymerizing a first monomer capable of providing at least one electron donating moiety and a second monomer and a third monomer capable of providing at least two electron accepting moieties. Accordingly, the copolymer may be at least a terpolymer.

In order to obtain the aforementioned copolymer, the second monomer and the third monomer capable of providing an electron accepting moiety and the first monomer capable of providing an electron donating moiety may have terminal functional groups capable of reacting with each other. For example, the second monomer and the third monomer may have a halogen group as a terminal functional group, and the first monomer may have a metal salt such as trimethyl tin as a terminal functional group.

By polymerizing these first, second, and third monomers, a portion of the first monomer may react with the second monomer to form a first repeating unit, and a portion of the first monomer may react with the third monomer to form a second repeating unit. Additionally, by adjusting a supply ratio of the first, second, and third monomers, the ratio of the first repeating unit and the second repeating unit may also be adjusted. However, the polymerization reaction is not limited to this and may be performed using various monomers in various ratios.

The numbers (quantities) of first repeating units and second repeating units in the copolymer (e.g., the quantities of units of the first repeating unit and the second repeating unit in the copolymer) may be, for example, 1 to 1000, 1 to 800, 2 to 1000, 2 to 800, 5 to 800, and 5 to 700, 1, 5 to 500, or 5 to 300, respectively, but are not limited thereto. For example, a sum of the numbers of first and second repeating units in the copolymer (e.g., a sum of a first repeating unit quantity of units of the first repeating unit and a second repeating unit quantity of units of the second repeating unit in the copolymer) may not exceed 2000.

The copolymer may further include a third repeating unit in addition to the first and second repeating units described above. For example, the third repeating unit may be different from the first repeating unit and the second repeating unit, respectively, and may include an electron donating moiety and an electron accepting moiety. For example, the third repeating unit may provide flexibility to the copolymer. For example, the third repeating unit may provide stretchability to the copolymer.

A weight average molecular weight of the copolymer may be, for example, about 5,000 Da to about 500,000 Da, and within the above range, for example, may be about 10,000 Da to about 300,000 Da or about 30,000 Da to about 250,000 Da.

The above-described copolymer may be formed into a copolymer film (also referred to herein interchangeably as a thin film). The copolymer film may be a deposition film formed by deposition or a coating film formed by a solution process. The coating film may be formed from a solution of the aforementioned copolymer dissolved in an organic solvent, and the organic solvent may be, for example, but not limited to, chloroform, tetrachloroethane, tetrahydrofuran, toluene, tetralin, decalin, anisole, xylene, ethyl acetate, methyl ethyl ketone, dimethyl formamide, chlorobenzene, dichlorobenzene, trichlorobenzene, propylene glycol monomethyl ether amine (PGMEA) or any combination thereof.

The copolymer film may further include a binder and/or an elastomer, in addition to the aforementioned copolymer. The binder may improve the dispersibility of the aforementioned copolymer, and may be, for example, polystyrene, but is not limited thereto. The elastomer may be mixed with the aforementioned copolymer to provide stretchability, and may be, for example, polyorganosiloxane, polyamide, polyimide, polyamidoimide, polyisobutene, polyolefin, polyester, polyurethane, or any combination thereof, but is not limited to thereto.

For example, the copolymer film may be a stretchable copolymer film. The stretchable copolymer film may flexibly respond to external forces or external movements such as twisting, pressing and pulling due to the stretching characteristics of the polymer described above, and may be easily restored to its original state.

The elastic modulus of the stretchable copolymer film may be, for example, less than about 10⁷ Pa, and within the above range, for example, may be greater than or equal to about 10 Pa and less than about 10⁷ Pa.

For example, the elongation rate of the stretchable copolymer film may be greater than or equal to about 10%, within the above range, about 10% to about 1000%, about 10% to about 800%, about 10% to about 500%, about 10% to about 300%, about 10% to about 200%, about 10% to about 100%, about 10% to about 90%, about 10% to about 80%, about 10% to about 70%, about 10% to about 60%, about 10% to about 50%, about 10% to about 40%, about 20% to about 70%, about 20% to about 60%, about 20% to about 50%, or about 20% to about 40%. Here, the elongation rate may be a percentage of a length change that is increased to a breaking point with respect to the initial length. For example, when the stretchable copolymer film is stretched, the change in the electrical characteristics of the stretchable copolymer film may be relatively small.

For example, when the stretchable copolymer film is stretched by about 30%, the change in the charge mobility of the stretchable copolymer film may be less than or equal to about 10%, less than or equal to about 8%, less than or equal to about 7%, less than or equal to about 5%, less than or equal to about 3%, or less than or equal to about 2%, or less than or equal to about 1%.

Since the copolymer film may have good semiconductor characteristics and high charge mobility, the copolymer film may be applied to various devices that require organic semiconductors.

For example, the copolymer film including the aforementioned polymer may be applied to as an organic semiconductor to a thin film transistor, as a charge transport layer and/or an active layer in electronic devices such as a display device, a solar cell, an organic light emitting diode (OLED) display, and an organic sensor. The electronic device may be, for example, a flexible and/or stretchable electronic device, and may be a wearable device and/or a skin-like device.

Hereinafter, an example of a thin film transistor including the aforementioned copolymer will be described with reference to the drawings.

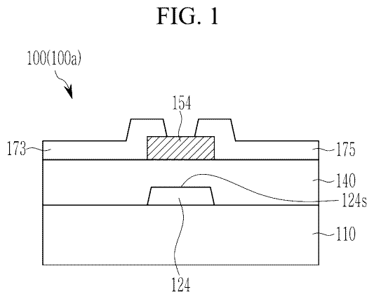

FIGS. 1, 2, and 3 are cross-sectional views each showing thin film transistors 100 according to some example embodiments.

Referring to FIGS. 1, 2, and 3, a thin film transistor 100 according to some example embodiments includes a gate electrode 124, an organic semiconductor 154 overlapped with the gate electrode 124 (e.g., overlapped in a direction perpendicular to a surface 124s of the gate electrode 124 facing the organic semiconductor 154), and a source electrode 173 and a drain electrode 175 electrically connected to the organic semiconductor 154. In some example embodiments, the organic semiconductor 154 may include the copolymer according to the example embodiments.

First, referring to FIG. 1, a thin film transistor 100 according to some example embodiments may be a thin film transistor 100a having a bottom gate and top contact structure. Specifically, a thin film transistor 100 according to some example embodiments includes a gate electrode 124 on a substrate 110; a gate insulating layer 140 on the gate electrode 124; an organic semiconductor 154 on the gate insulating layer 140; and a source electrode 173 and a drain electrode 175 electrically connected to the organic semiconductor 154.

A gate electrode 124 is formed on a substrate 110 made of transparent glass, silicon, or plastic. The gate electrode 124 is connected to a gate line (not shown) transferring a gate signal. The gate electrode 124 may be made of gold (Au), copper (Cu), nickel (Ni), aluminum (AI), molybdenum (Mo), chromium (Cr), tantalum (Ta), titanium (Ti), an alloy thereof, or any combination thereof.

A gate insulating layer 140 is formed on the gate electrode 124. The gate insulating layer 140 may be made of an organic material and/or an inorganic material. Examples of the organic material may include a soluble polymer compound such as a polyvinyl alcohol-based compound, a polyimide-based compound, a polyacrylic compound, a polystyrene-based compound, and benzocyclobutene (BCB), and examples of the inorganic material may include a silicon nitride (SiNₓ) and a silicon oxide (SiO₂).

An organic semiconductor 154 is formed on the gate insulating layer 140. The organic semiconductor 154 may include the aforementioned copolymer and may be the aforementioned copolymer film. The organic semiconductor 154 may be formed by preparing the aforementioned copolymer in a solution form and using a solution process such as spin coating, slit coating or inkjet printing. The organic semiconductor 154 may be formed by vacuum deposition or thermal evaporation of the aforementioned copolymer.

A source electrode 173 and a drain electrode 175 are formed on the organic semiconductor 154. The source electrode 173 and the drain electrode 175 face each other on the organic semiconductor 154 in the center of the gate electrode 124 (e.g., such that the organic semiconductor 154 may be between the source electrode 173 and the drain electrode 175). The source electrode 173 is electrically connected to the data line (not shown) configured to transfer the data signal. The source electrode 173 and the drain electrode 175 may include at least one metal selected from gold (Au), copper (Cu), nickel (Ni), aluminum (AI), molybdenum (Mo), chromium (Cr), tantalum (Ta), titanium (Ti), an alloy thereof, or any combination thereof.

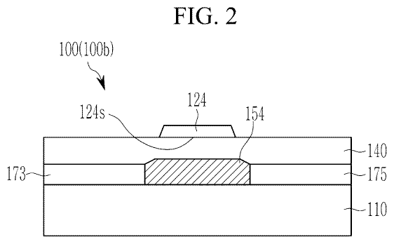

Referring to FIG. 2, the thin film transistor 100 according to some example embodiments may be a thin film transistor 100b having a top gate and top contact structure, unlike some example embodiments, including the example embodiments shown in FIG. 1. Specifically, a thin film transistor 100 according to some example embodiments includes an organic semiconductor 154 on the substrate 110; a source electrode 173 and a drain electrode 175 electrically connected to the organic semiconductor 154; a gate insulating layer 140 on the organic semiconductor 154, the source electrode 173, and the drain electrode 175; and a gate electrode 124 on the gate insulating layer 140.

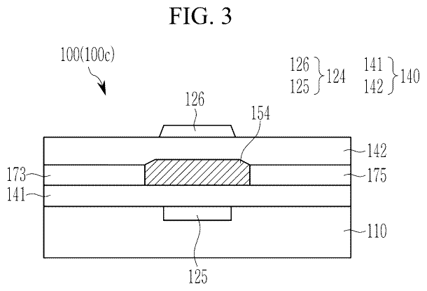

Referring to FIG. 3, the thin film transistor 100 according to some example embodiments may be a thin film transistor 100c having a dual gate and bottom/top contact structure, unlike some example embodiments, including the example embodiments shown in FIGS. 1 and 2. For example, the gate electrode 124 may include a first gate electrode 125 and a second gate electrode 126, and the gate insulating layer 140 may include a first gate insulating layer 141 and a second gate insulating layer 142. Specifically, a thin film transistor 100 according to some example embodiments includes an organic semiconductor 154 on the substrate 110; a first gate electrode 125 positioned under the organic semiconductor 154; a second gate electrode 126 positioned on the organic semiconductor 154; a first gate insulating layer 141 between the organic semiconductor 154 and the first gate electrode 125; a second gate insulating layer 142 between the organic semiconductor 154 and the second gate electrode 126; and a source electrode 173 and a drain electrode 175 electrically connected to the organic semiconductor 154. The first gate electrode 125 may be embedded in the substrate 110 or may be formed by impurity doping. The first gate electrode 125, the organic semiconductor 154, and the second gate electrode 126 may be overlapped with each other such that the organic semiconductor 154 is at least partially overlapped between the first gate electrode 125 and the second gate electrode 126.

Here, examples of the thin film transistor 100 have been described, but the present inventive concepts are not limited thereto and may be equally applied to thin film transistors of all structures.

The thin film transistor 100 may be applied to (e.g., included in) a switch and/or driving device of various electronic devices, and the electronic device may be, for example, display devices, semiconductor devices, sensing devices, or lighting devices, for example liquid crystal displays, organic light emitting display devices, quantum dot display devices, electrophoretic displays, organic photoelectric devices, and organic sensors, but is not limited thereto. The electronic device including the thin film transistor may be for example flexible and stretchable electronic device, and may be a wearable device and/or a skin-like device.

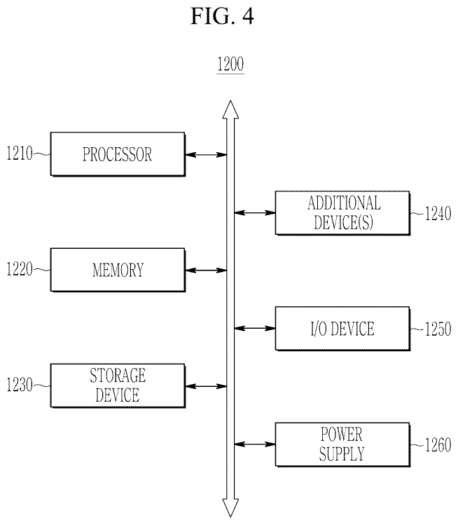

FIG. 4 illustrates a block diagram showing an electronic device according to some example embodiments.

Referring to FIG. 4, the electronic device 1200 may include a processor 1210, a memory 1220, a storage device 1230, one or more additional devices 1240, an input/output device 1250, and a power supply 1260, and these components may communicate with each other through a bus. The one or more additional devices 1240 may include one or more of a display device (e.g., an LED display screen, and OLED display screen, or the like), an image sensor (e.g., a camera), or any combination thereof. Any of the processor 1210, the memory 1220, the storage device 1230, the one or more additional devices 1240, the input/output device 1250, and/or the power supply 1260 may be omitted from the electronic device 1200. Any of the processor 1210, the memory 1220, the storage device 1230, the one or more additional devices 1240, the input/output device 1250, and/or the power supply 1260 may include one or more thin film transistors 100 according to any of the example embodiments, including one or more thin film transistors 100 according to any of the example embodiments shown in any of FIGS. 1 to 3.

In some example embodiments, the processor 1210 may perform specific calculations or tasks necessary for an operation of the electronic device 1200. The memory 1220 and storage device 1230 may store data necessary for the operation of the electronic device 1200. For example, the processor 1210 may include a microprocessor, a central processing unit (CPU), an application processor (AP), etc., the memory 1220 may include a volatile memory and/or a non-volatile memory, and the storage device 1230 may include a solid state drive (SSD), a hard disk drive (HDD), a CD-ROM, etc. The input/output device 1250 may include an input means such as a keyboard, a keypad, a mouse, etc., and an output means such as a printer, a display, etc. The power supply 1260 may supply an operating voltage necessary for the operation of the electronic device 1200.

As described herein, any devices, systems, modules, portions, units, controllers, circuits, and/or portions thereof according to any of the example embodiments, and/or any portions thereof (including, without limitation, electronic device 1200, processor 1210, memory 1220, storage device 1230, one or more additional devices 1240, input/output device 1250, power supply 1260, any portion thereof, or the like) may include, may be included in, and/or may be implemented by one or more instances of processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a solid state drive (SSD), storing a program of instructions, and a processor (e.g., CPU) configured to execute the program of instructions to implement the functionality and/or methods performed by some or all of any devices, systems, modules, portions, units, controllers, circuits, and/or portions thereof according to any of the example embodiments.

Hereinafter, some example embodiments are illustrated in more detail with reference to examples. However, the scope of the inventive concepts is not limited to such examples.

### SYNTHESIS EXAMPLES

### Synthesis Example 1: Synthesis of Monomer 1

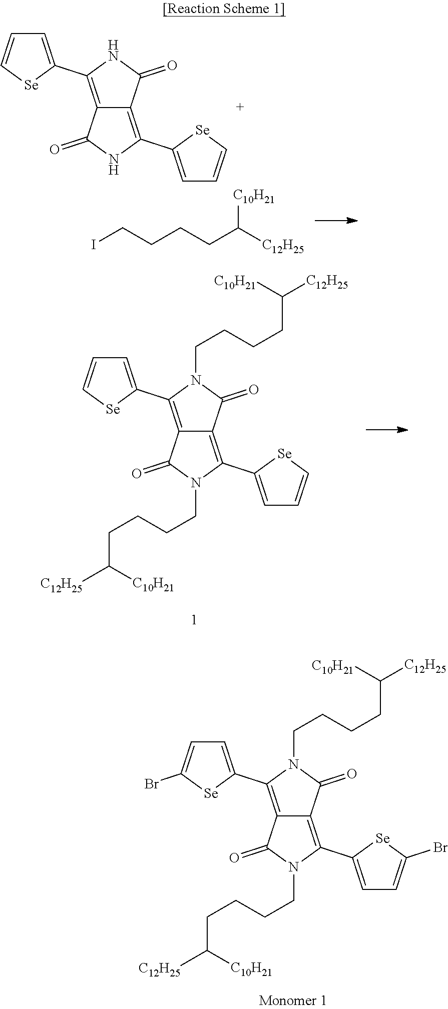

### (1) Synthesis of Intermediate 1

In a 250 ml reaction flask, 3,6-di(selenophen-2-yl)-2,5-dihydropyrrolo[3,4-c]pyrrole-1,4-dione (1.5 g, 3.8 mmol), potassium carbonate (2.1 g, 15.2 mmol), and DMF (40 ml) are added. The reactant in the flask is stirred and heated to 120° C. After the heating to 120° C., 11-(4-iodobutyl)tricosane (5.78 g, 11.4 mmol) is slowly added thereto. After a reaction for about 24 hours, the reactant is cooled to room temperature. The cooled reactant is poured into an excessive amount of distilled water and subsequently, extracted with chloroform. The extracted chloroform organic layer is dried with MgSO₄ and filtered. The filtered organic layer is distilled under a reduced pressure, concentrated, and purified through silica gel column (n-hexane:dichloromethane=1:1) to obtain a purple solid of Intermediate 1 (0.85 g, a yield: 19.4%).

### (2) Synthesis of Monomer 1

In a 250 ml reaction flask, Intermediate 1 (1.4 g, 1.2 mmol), N-bromosuccinimide (0.45 g, 2.5 mmol), and chloroform (100 ml) are added and completely dissolved at room temperature. The dissolved reactant is wrapped with an aluminum foil and then, stirred for about 24 hours. After a reaction, the resultant is washed with distilled water to recover an organic layer. The recovered organic layer is dried with MgSO₄ and filtered. The filtered organic layer is distilled under a reduced pressure, concentrated, and purified through silica gel column (n-hexane:dichloromethane=2:1) to obtain a purple solid of Monomer 1 (1.27 g, a yield: 80.0%).

1H NMR (400 MHz, CDCl₃): δ 8.65 (d, 2H), 7.28 (d, 2H), 4.00-3.95 (t, 4H), 1.73-1.69 (t, 4H), 1.40-1.27 (m, 90H), 0.92-0.87 (m, 12H)

### Synthesis Example 2: Synthesis of Monomer 2

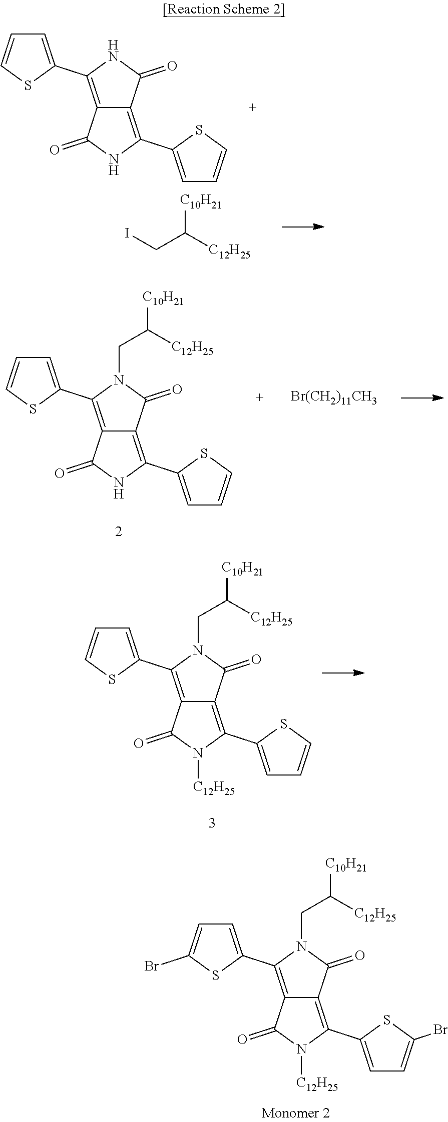

### (1) Synthesis of Intermediate 2

In a 250 ml reaction flask, 3,6-di(thiophen-2-yl)-2,5-dihydropyrrolo[3,4-c]pyrrole-1,4-dione (3.0 g, 10.0 mmol), potassium carbonate (2.8 g, 20.0 mmol), and DMF (90 ml) are added. The reactant in the flask is stirred and heated to 120° C. After the heating to 120° C., 11-(iodomethyl)tricosane (4.6 g, 10.0 mmol) is slowly added thereto. After a reaction for about 24 hours, the reactant is cooled to room temperature, and the cooled reactant is poured into an excessive amount of distilled water and subsequently, extracted with chloroform. The extracted chloroform organic layer is dried with MgSO₄ and filtered. The filtered organic layer is distilled under a reduced pressure, concentrated, and passed through silica gel column (dichloromethane 100%) to obtain Intermediate 2.

### (2) Synthesis of Intermediate 3

In a 250 ml reaction flask, Intermediate 2 (1.58 g, 2.5 mmol), potassium carbonate (0.69 g, 4.9 mmol), and DMF (60 ml) are added. The reactant in the flask is stirred and heated to 120° C. After the heating to 120° C., 1-bromododecane (0.92 g, 3.7 mmol) is slowly added thereto. After a reaction for about 24 hours, the reactant is cooled to room temperature. The cooled reactant is poured into an excessive amount of distilled water and subsequently extracted with chloroform. The extracted chloroform organic layer is dried with MgSO₄ and filtered. The filtered organic layer is distilled under a reduced pressure, concentrated, and purified through silica gel column (n-hexane:dichloromethane=1:1) to obtain a purple solid of Intermediate 3 (1.0 g, a yield: 51.6%).

1H NMR (400 MHz, CDCl₃): δ 8.95-8.94 (m, 1H), 8.85-8.84 (m, 1H), 7.63-7.61 (m, 2H), 7.29-7.25 (m, 2H), 4.08-4.00 (m, 4H), 1.91-1.88 (m, 1H), 1.79-1.71 (m, 2H), 1.44-1.21 (m, 58H), 0.89-0.85 (m, 9H)

### (3) Synthesis of Monomer 2

In a 250 ml reaction flask, Intermediate 3 (1.0 g, 1.3 mmol), N-bromosuccinimide (0.48 g, 2.7 mmol), and chloroform (100 ml) are added and completely dissolved at room temperature. The dissolved reactant is wrapped with an aluminum foil and then, stirred for about 24 hours. After a reaction, the resultant is washed with distilled water to recover an organic layer. The recovered organic layer is dried with MgSO₄ and filtered. The filtered organic layer is distilled under a reduced pressure, concentrated, and purified through silica gel column (n-hexane:dichloromethane=2:1) to obtain a purple solid of Monomer 2 (0.66 g, a yield: 53.5%).

1H NMR (400 MHz, CDCl₃): δ 8.68 (d, 1H), 8.59 (d, 1H), 7.22 (d, 2H), 3.98 (t, 2H), 3.91 (d, 2H), 1.88-1.85 (m, 1H), 1.76-1.68 (m, 2H), 1.41-1.22 (m, 58H), 0.90-0.86 (m, 9H)

### Synthesis Example 3: Synthesis of Monomer 3

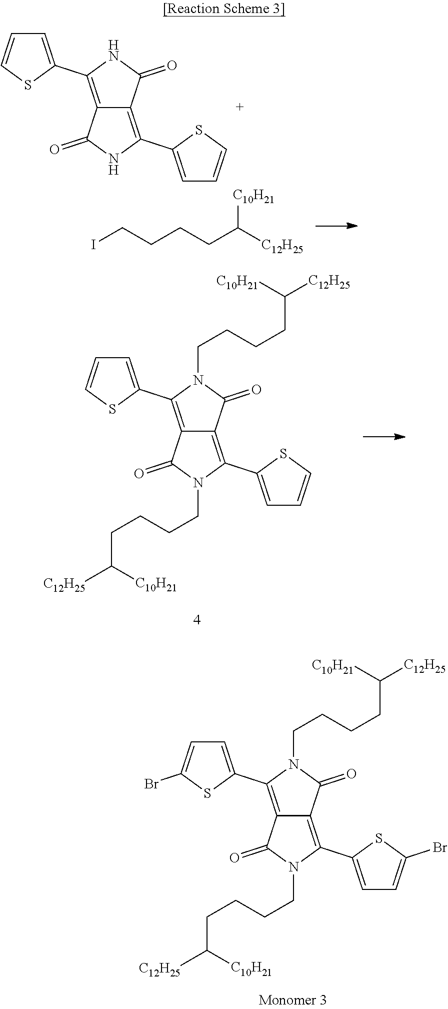

### (1) Synthesis of Intermediate 4

In a 250 ml reaction flask, 3,6-di(thiophen-2-yl)-2,5-dihydropyrrolo[3,4-c]pyrrole-1,4-dione (1.2 g, 3.9 mmol), potassium carbonate (3.0 g, 21.4 mmol), and DMF (55 ml) are added. The reactant in the flask is stirred and heated to 120° C. After the heating to 120° C., 11-(4-iodobutyl)tricosane (9.9 g, 19.5 mmol) is slowly added thereto. After a reaction, the reactant is cooled to room temperature. The cooled reactant is poured into an excessive amount of distilled water and subsequently, extracted with chloroform. The extracted chloroform organic layer is dried with MgSO₄ and filtered. The filtered organic layer is distilled under a reduced pressure, concentrated, and purified through silica gel column (n-hexane:dichloromethane=3:1) to obtain a purple solid of Intermediate 4 (1.3 g, a yield: 31.8%).

### (2) Synthesis of Monomer 3

In a 250 ml reaction flask, Intermediate 4 (1.3 g, 1.3 mmol), N-bromosuccinimide (0.46 g, 2.6 mmol), and chloroform (100 ml) are added and completely dissolved at room temperature. The dissolved reactant is wrapped with an aluminum foil and then, stirred for about 24 hours. After 24 hours, reaction, the resultant is washed with distilled water to recover an organic layer. The recovered organic layer is dried with MgSO₄ and filtered. The filtered organic layer is distilled under a reduced pressure, concentrated, and purified through silica gel column (n-hexane:dichloromethane=2:1) to obtain a purple solid of Monomer 3 (1.3 g, a yield: 86.0%).

1H NMR (400 MHz, CDCl₃): δ 8.71 (d, 2H), 7.26 (d, 2H), 4.02-3.97 (t, 4H), 1.73-1.69 (t, 4H), 1.40-1.27 (m, 90H), 0.92-0.87 (m, 12H)

### Synthesis Example 4: Synthesis of Monomer 4

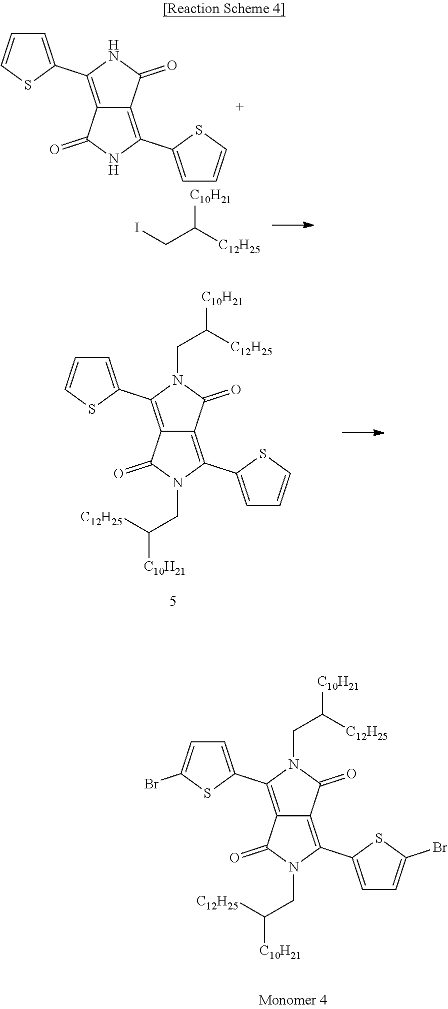

### (1) Synthesis of Intermediate 5

In a 250 ml reaction flask, 3,6-di(thiophen-2-yl)-2,5-dihydropyrrolo[3,4-c]pyrrole-1,4-dione (1.2 g, 3.9 mmol), potassium carbonate (3.0 g, 21.4 mmol), and DMF (55 ml) are added. The reactant in the flask is stirred and heated to 120° C. After the heating to 120° C., 11-(iodomethyl)tricosane (9.0 g, 19.5 mmol) is slowly added thereto. After a reaction, the reactant is cooled to room temperature. The cooled reactant is poured into an excessive amount of distilled water and subsequently, extracted with chloroform. The extracted chloroform organic layer is dried with MgSO₄ and filtered. The filtered organic layer is distilled under a reduced pressure, concentrated, and purified through silica gel column (n-hexane:dichloromethane=3:1) to obtain a purple solid of Intermediate 5 (1.5 g, a yield: 39.6%).

### (2) Synthesis of Monomer 4

In a 250 ml reaction flask, Intermediate 5 (1.5 g, 1.54 mmol), N-bromosuccinimide (0.56 g, 3.2 mmol), and chloroform (100 ml) are added and completely dissolved at room temperature. The dissolved reactant is wrapped with an aluminum foil and then, stirred for about 24 hours. After a reaction, the resultant is washed with distilled water to recover an organic layer. The recovered organic layer is dried with MgSO₄ and filtered. The filtered organic layer is distilled under a reduced pressure, concentrated, and purified through silica gel column (n-hexane:dichloromethane=2:1) to obtain a purple solid of Monomer 4 (1.4 g, a yield: 82.5%).

1H NMR (400 MHz, CDCl₃): 8.62-8.63 (d, 2H), 7.21-7.22 (d, 2H), 3.91-3.93 (d, 4H), 1.87 (m, 2H), 1.21-1.28 (m, 80H), 0.87 (t, 12H)

### Synthesis Example 5: Synthesis of Copolymer 1

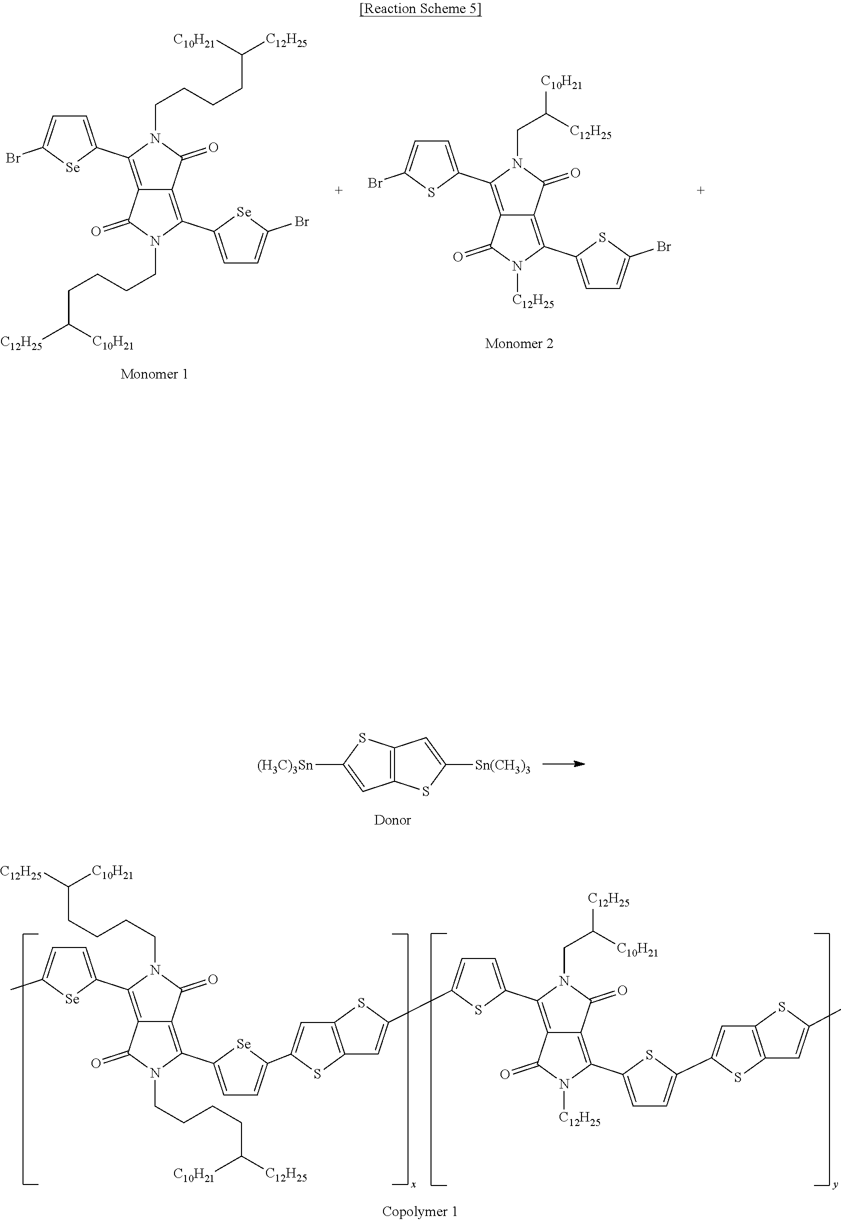

In a 50 ml reaction flask, Monomer 1 (223.9 mg, 0.17 mmol) of Synthesis Example 1, Monomer 2 (8.7 mg, 0.01 mmol) of Synthesis Example 2, 2,5-bis(trimethylstannyl)thieno[3,2-b]thiophene (a donor, 83.8 mg, 0.18 mmol), tris(dibenzylideneacetone)dipalladium (0) (8.2 mg, 0.01 mmol), tri(o-tolyl)phosphine (10.9 mg, 0.036 mmol), and chlorobenzene (15 mL) are added and dissolved. The reaction flask is changed to a nitrogen atmosphere and then, heated to 115° C. to proceed with a polymerization. After proceeding with the polymerization for 24 hours, the flask Is cooled to room temperature to obtain Polymer 1 (Copolymer 1, x=95, y=5). The cooled Polymer 1 is poured into an excessive amount of methanol to form precipitates. The precipitates are recovered through a pressure-reducing filter and immediately, subjected to Soxhlet purification. The Soxhlet purification uses a solvent such as methanol, acetone, n-hexane, and chloroform in order, and a solution finally extracted in the chloroform is precipitated in methanol and recovered in a film state.

Molecular weight analysis: measured at 160° C. by using an Agilent PL-GPC220 equipment and 1,2,4-trichlorobenzene as a developing solution.

Mp=173,423, Mn=80,051, Mw=204,886, Mz=385,008, Mv=355,774, PD=2.56

### Synthesis Example 6

Copolymer 1 (x=85, and y=15) is synthesized in the same manner as in Synthesis Example 5 except that the amounts of Monomer 1 (200.3 mg, 0.153 mmol) and Monomer 2 (26 mg, 0.027 mmol) are changed.

Mp=177,616, Mn=82,492, Mw=199,120, Mz=353,121, Mv=328,322, PD=2.41

### Synthesis Example 7

Copolymer 1 (x=75, and y=25) is synthesized in the same manner as in Synthesis Example 5 except that the amounts of Monomer 1 (176.7 mg, 0.135 mmol) and Monomer 2 (43.3 mg, 0.045 mmol) are changed.

Mp=177,616, Mn=89,001, Mw=217,417, Mz=397,119, Mv=367,631, PD=2.44

### Synthesis Example 8: Synthesis of Copolymer 2

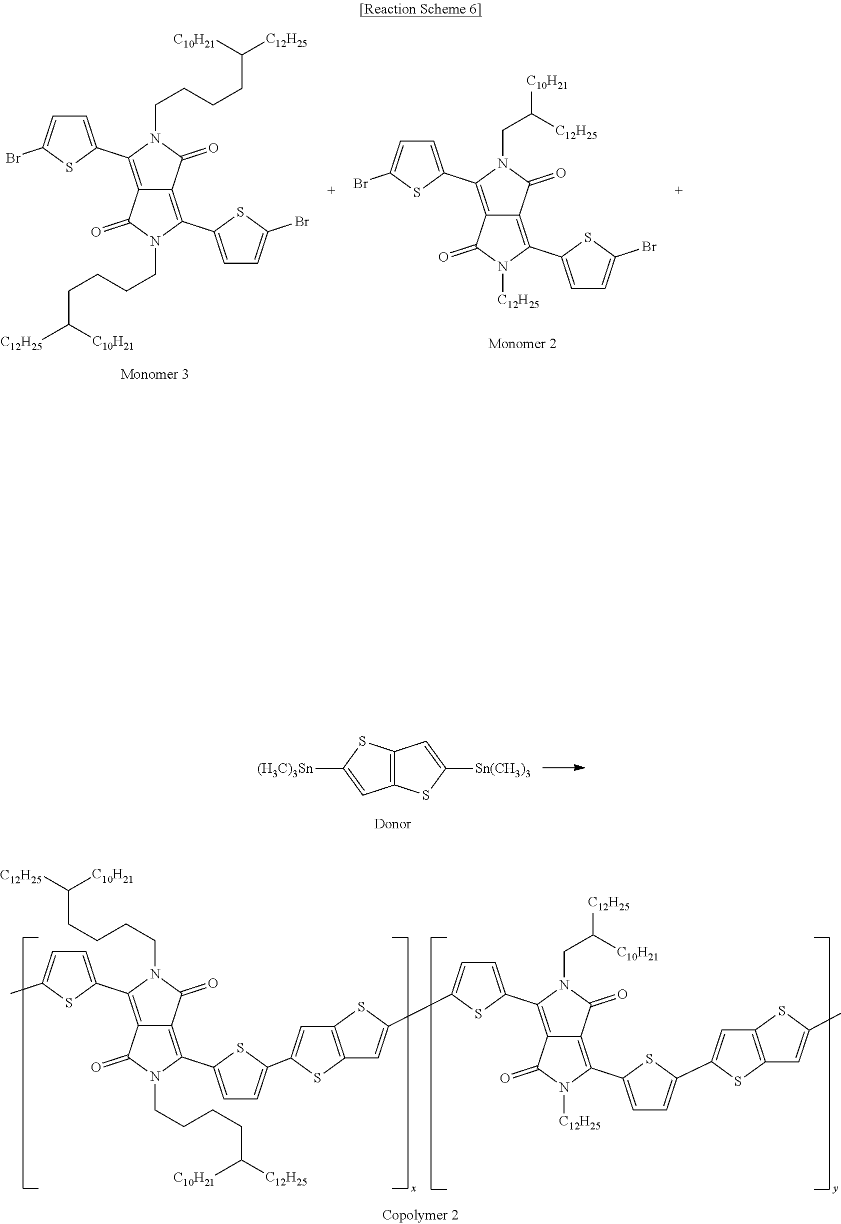

x=75, and y=25

In a 50 ml reaction flask, Monomer 3 (164.1 mg, 0.135 mmol) of Synthesis Example 3, Monomer 2 (43.3 mg, 0.045 mmol) of Synthesis Example 2, 2,5-bis(trimethylstannyl)thieno[3,2-b]thiophene (83.8 mg, 0.18 mmol), tris(dibenzylideneacetone)dipalladium (0) (8.2 mg, 0.01 mmol), tri(o-tolyl)phosphine (10.9 mg, 0.036 mmol), and chlorobenzene (15 mL) are added and dissolved. The reaction flask is changed to a nitrogen atmosphere and heated to 115° C. to proceed with a polymerization. After proceeding with the polymerization for 24 hours, the flask is cooled to room temperature to obtain Copolymer 2 (x=75, y=25). The cooled Copolymer 2 is poured into an excessive amount of methanol to form precipitates. The precipitates are filtered and recovered through a pressure-reducing filter and immediately, subjected to Soxhlet purification. The Soxhlet purification uses a solvent such as methanol, acetone, n-hexane, and chloroform in order, and a solution finally extracted in the chloroform is precipitated in methanol and recovered in a film state.

Mp=157,663, Mn=97,889, Mw=224,622, Mz=414,864, Mv=382,710, PD=2.29

### Synthesis Example 9: Synthesis of Copolymer 3

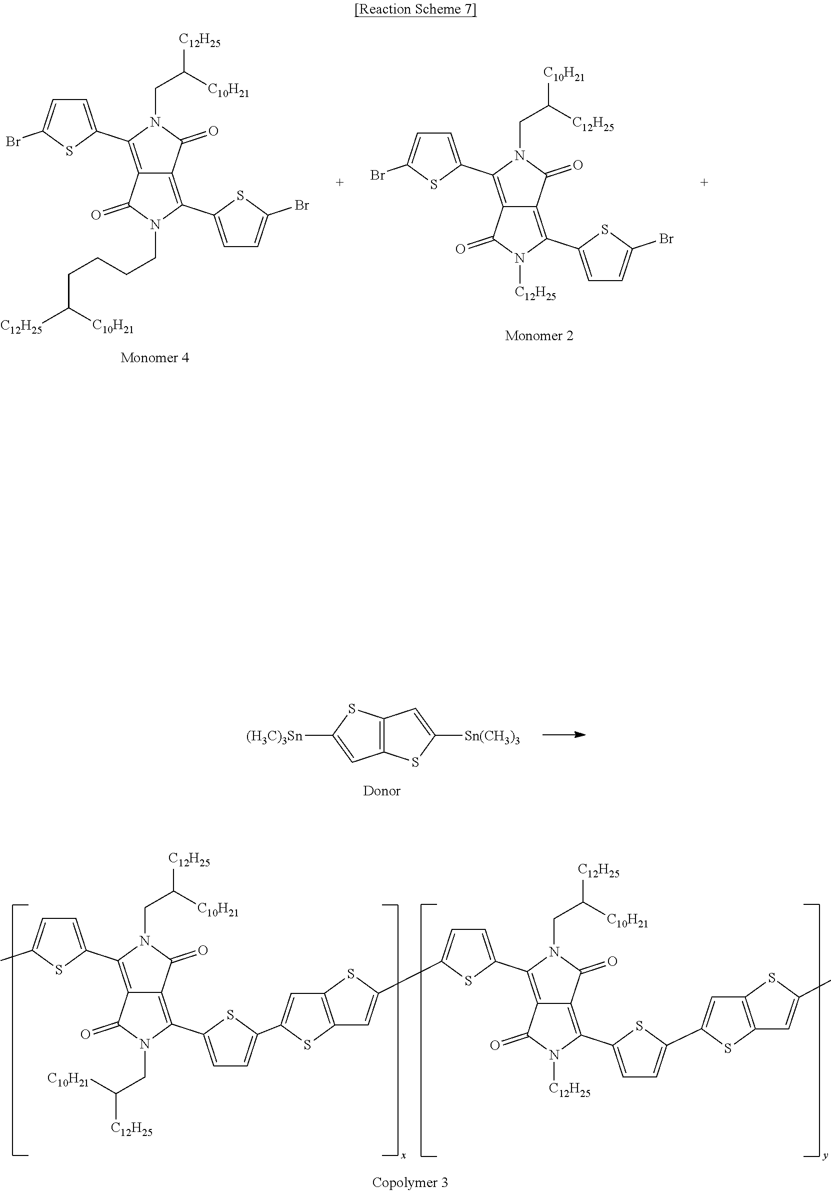

x=75 and y=25

In a 50 ml reaction flask, Monomer 4 (152.7 mg, 0.135 mmol) of Synthesis Example 4, Monomer 2 (43.3 mg, 0.045 mmol) of Synthesis Example 2, 2,5-bis(trimethylstannyl)thieno[3,2-b]thiophene (a donor, 83.8 mg, 0.18 mmol), tris(dibenzylideneacetone)dipalladium (0) (8.2 mg, 0.01 mmol), tri(o-tolyl)phosphine (10.9 mg, 0.036 mmol), and chlorobenzene (15 mL) are added and dissolved. The reaction flask is changed to nitrogen atmosphere and heated to 115° C. to proceed with a polymerization. After the polymerization for about 24 hours, the flask is cooled to room temperature to obtain Copolymer 3 (x=75, y=25). The cooled Copolymer 3 is poured into an excessive amount of methanol to form precipitates. The precipitates are recovered through a pressure-reducing filter and immediately, subjected to Soxhlet purification. The Soxhlet purification uses a solvent such as methanol, acetone, n-hexane, and chloroform in order, and a solution finally extracted in the chloroform is poured into methanol and recovered in a film state.

Mp=165,347, Mn=102,701, Mw=229,484, Mz=415,772, Mv=384,740, PD=2.23

### Comparative Synthesis Example 1: Synthesis of Polymer 1

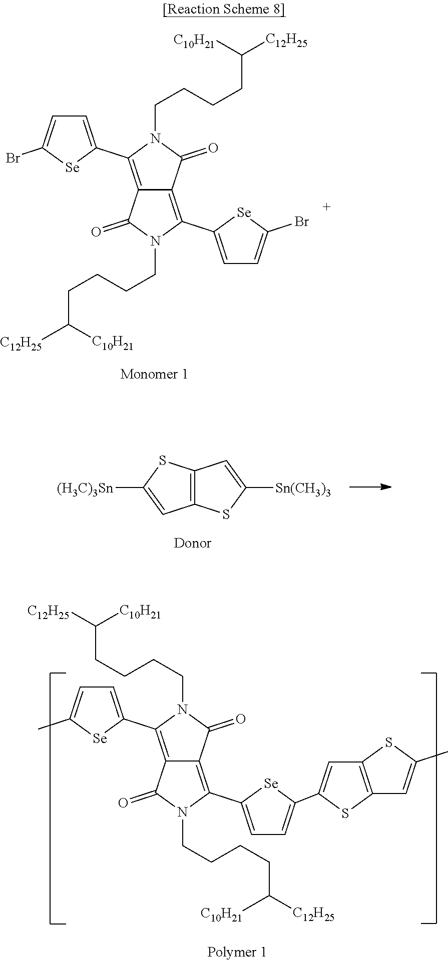

In a 50 ml reaction flask, Monomer 1 (235.7 mg, 0.18 mmol) of Synthesis Example 1, 2,5-bis(trimethylstannyl)thieno[3,2-b]thiophene (a donor, 83.8 mg, 0.18 mmol), tris(dibenzylideneacetone)dipalladium (0) (8.2 mg, 0.01 mmol), tri(o-tolyl)phosphine (10.9 mg, 0.036 mmol), and chlorobenzene (15 mL) are added and dissolved. The reaction flask is changed to a nitrogen atmosphere and then, heated to 115° C. to proceed with a polymerization. After proceeding with the polymerization for 24 hours, the flask is cooled to room temperature to obtain Polymer 1. The cooled Polymer 1 is poured into an excessive amount of methanol to form precipitates. The precipitates are recovered through a pressure-reducing filter and immediately, subjected to Soxhlet purification. The Soxhlet purification uses a solvent such as methanol, acetone, n-hexane, and chloroform in order, and a solution finally extracted in the chloroform is poured into methanol and recovered in a film state.

Mp=183,153, Mn=95,992, Mw=208,028, Mz=359,435, Mv=335,680, PD=2.17

### Comparative Synthesis Example 2: Synthesis of Polymer 2

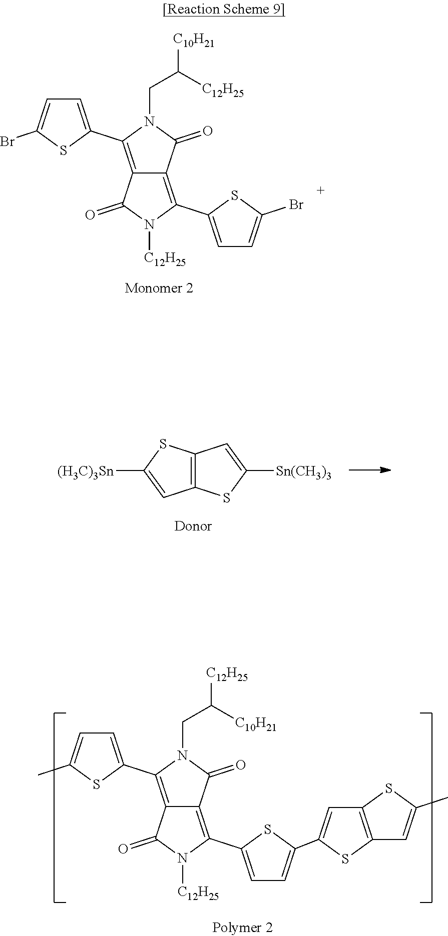

In a 50 ml reaction flask, Monomer 2 (173.3 mg, 0.18 mmol) of Synthesis Example 2, 2,5-bis(trimethylstannyl)thieno[3,2-b]thiophene (a donor, 83.8 mg, 0.18 mmol), tris(dibenzylideneacetone)dipalladium (0) (8.2 mg, 0.01 mmol), tri(o-tolyl)phosphine (10.9 mg, 0.036 mmol), and chlorobenzene (15 mL) are added and dissolved. The reaction flask is changed to a nitrogen atmosphere and heated to 115° C. to proceed with polymerization. After proceeding with the polymerization for about 24 hours, the flask is cooled to room temperature to obtain Polymer 2. The cooled Polymer 2 is poured into an excessive amount of methanol to form precipitates. The precipitates are recovered through a pressure-reducing filter and immediately, subjected to Soxhlet purification. The Soxhlet purification uses a solvent such as methanol, acetone, n-hexane, and chloroform in order, and a solution finally extracted in the chloroform is precipitated in methanol and recovered in a film state.

Mp=150,348, Mn=58,335, Mw=207,006, Mz=475,397, Mv=432,182, PD=3.55

### Evaluation I

The copolymer of Synthesis Example 7 and the polymer of Comparative Synthesis Example 1 are evaluated with respect to light absorption characteristics.

The light absorption characteristics are measured from an absorption spectrum within a wavelength region of 300 nm to 1200 nm by using a UV-1800 spectrometer (Shimadzu Scientific Instruments).

The results are shown in FIG. 4 and Table 1.

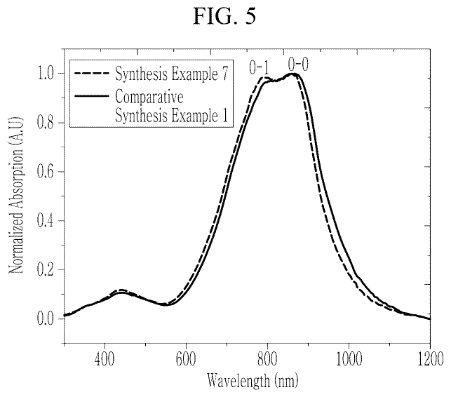

FIG. 5 is a graph showing light absorption characteristics of the copolymer of Synthesis Example 7 and the polymer of Comparative Synthesis Example 1.

TABLE 1

| | Absorption peak | Absorption peak | |
|---|---|---|---|
| | wavelength 1 | wavelength 2 | A(λₚₑₐₖ₁)/ |
| | (λₚₑₐₖ₁, nm) | (λₚₑₐₖ₂, nm) | A(λₚₑₐₖ₂) |
| Synthesis Example 7 | 860 | 793 | 1.01 |
| Comparative Synthesis | 867 | 795 | 1.04 |
| Example 1 | | | |

* A(λₚₑₐₖ₁)/A(λₚₑₐₖ₂): a ratio of absorbance at absorption peak wavelength 1 to absorbance at absorption peak wavelength 2

In Table 1, the absorption peak wavelength 1 is a wavelength related to J-aggregate of a polymer (copolymer) film, and the absorption peak wavelength 2 is a wavelength related to H-aggregate of the polymer (copolymer) film.

Referring to FIG. 5 and Table 1, the copolymer film of Synthesis Example 7, compared with the polymer film of Comparative Synthesis Example 1, is confirmed to have A(λₚₑₐₖ₁)/A(λₚₑₐₖ₂) approaching 1. This may mean that the copolymer film of Synthesis Example 7 exhibits increased light absorption characteristics (A(λₚₑₐₖ₂)) at short wavelengths, which is caused by the H-aggregation, and accordingly, it may be confirmed that the H-aggregation of the copolymer film of Synthesis Example 7 is strengthened in relation to the polymer film of Comparative Synthesis Example 1. Since the strengthened H-aggregation in polymer crystal characteristics means an increase in crystallinity due to inter-chain interaction between molecule chains, the copolymer film of Synthesis Example 7 may have high crystallinity in relation to the polymer film of Comparative Synthesis Example 1, and accordingly, electrical characteristics (e.g., charge mobility) of a thin film transistor including the same may be relatively improved in relation to a thin film transistor including the polymer of Comparative Synthesis Example 1.

### MANUFACTURING OF THIN FILM TRANSISTORS

### Example 1

A self-assembled monolayer (SAM) is formed with octadecyl trichlorosilane (ODTS) on a silicon wafer with a 300 nm-thick silicon oxide, and a copolymer solution prepared by dissolving the copolymer of Synthesis Example 5 in chlorobenzene at a concentration of about 1 wt % is spin-coated thereon at 1500 rpm for 60 seconds and then, heat-treated at 190° C. for 1 hour to form a 50 nm-thick organic semiconductor. Subsequently, on the organic semiconductor, molybdenum oxide (MoOₓ, 0<x≤2) and gold (Au) are sequentially thermally deposited with thickness 10 nm and 100 nm, respectively, to form a source electrode and a drain electrode and resultantly, manufacture a thin film transistor. a channel width (W) and a channel length (L) of the thin film transistor are 100 μm and 1000 μm, respectively.

### Example 2

A thin film transistor is manufactured in the same manner as in Example 1 except that the copolymer of Synthesis Example 6 instead of the copolymer of Synthesis Example 5 is used to form an organic semiconductor.

### Example 3

A thin film transistor is manufactured in the same manner as in Example 1 except that the copolymer of Synthesis Example 7 instead of the copolymer of Synthesis Example 5 is used to form an organic semiconductor.

### Example 4

A thin film transistor is manufactured in the same manner as in Example 1 except that the copolymer of Synthesis Example 8 instead of the copolymer of Synthesis Example 5 is used to form an organic semiconductor.

### Example 5

A thin film transistor is manufactured in the same manner as in Example 1 except that the copolymer of Synthesis Example 9 instead of the copolymer of Synthesis Example 5 is used to form an organic semiconductor.

### Comparative Example 1

A thin film transistor is manufactured in the same manner as in Example 1 except that the copolymer of Comparative Synthesis Example 1 instead of the copolymer of Synthesis Example 5 is used to form an organic semiconductor.

### Comparative Example 2

A thin film transistor is manufactured in the same manner as in Example 1 except that the copolymer of Comparative Synthesis Example 2 instead of the copolymer of Synthesis Example 5 is used to form an organic semiconductor.

### Evaluation II

The thin film transistors according to Examples and Comparative Examples are evaluated with respect to electrical characteristics.

The electrical characteristics are measured by using Keithley 4200A (SEMI SYSTEM W/2 MPSMU & FPD), while a gate voltage of +10 V to −30 V is applied to the thin film transistors in an atmospheric state.

The results are shown in Table 2.

TABLE 2

| | Hole mobility | |
|---|---|---|
| | (cm²/Vs) | Iₒₙ/I_{off} |
| Example 1 | 0.54 | 6.4 × 10⁴ |
| Example 2 | 0.71 | 5.7 × 10⁴ |
| Example 3 | 1.14 | 3.1 × 10⁴ |
| Example 4 | 0.97 | 5.2 × 10⁴ |
| Example 5 | 0.55 | 7.8 × 10⁴ |
| Comparative | 0.53 | 3.9 × 10⁴ |
| Example 1 | | |
| Comparative | 0.38 | 4.3 × 10³ |
| Example 2 | | |

Referring to Table 2, the thin film transistors of Examples, compared to the thin film transistor of Comparative Examples, exhibit improved electrical characteristics (at least one of hole mobility or current characteristics). In addition, comparing the thin film transistors according to Examples 1 to 3, it is confirmed that charge mobility may be effectively controlled depending on a ratio of repeating units (x:y).

While the inventive concepts have been described in connection with what is presently considered to be practical example embodiments, it is to be understood that the inventive concepts are not limited to such example embodiments, but, on the contrary, the inventive concepts are intended to cover various modifications and equivalent arrangements included within the spirit and scope of the appended claims.

What is claimed is:

1. A copolymer, comprising:
a first repeating unit represented by Chemical Formula 1, and
a second repeating unit represented by Chemical Formula 2: 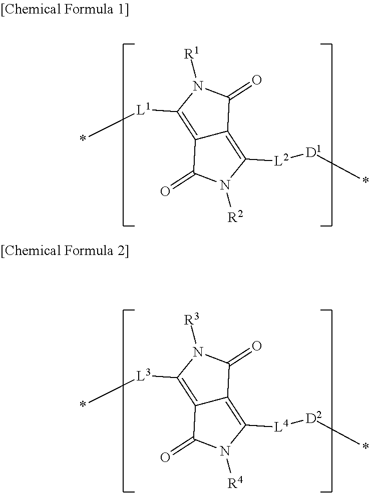
wherein, in Chemical Formula 1 and Chemical Formula 2,
D¹ and D² are each independently an electron donating moiety,
L¹ to L⁴ are each independently a single bond, a substituted or unsubstituted C1 to C20 alkylene group, a substituted or unsubstituted C6 to C30 arylene group, a substituted or unsubstituted C3 to C30 divalent heterocyclic group, a fused ring thereof, or any combination thereof,
R¹ and R² are each independently a substituted or unsubstituted C5 to C50 branched alkyl group,
one of R³ or R⁴ is a substituted or unsubstituted C1 to C50 linear alkyl group, and another one of R³ or R⁴ is a substituted or unsubstituted C5 to C50 branched alkyl group, and
* is a linking point.

2. The copolymer of claim 1, wherein, in Chemical Formula 1 and Chemical Formula 2, D¹ and D² each independently comprise a substituted or unsubstituted C6 to C30 arylene group; a substituted or unsubstituted C3 to C30 divalent heterocyclic group including at least one selected from O, S, Se, Te, or Si; a fused ring thereof; or any combination thereof.

3. The copolymer of claim 2, wherein, in Chemical Formula 1 and Chemical Formula 2, D¹ and D² each independently comprise one or more substituted or unsubstituted phenylene groups; one or more substituted or unsubstituted naphthylene groups; one or more substituted or unsubstituted anthracenylene groups; one or more substituted or unsubstituted phenanthrenylene groups; one or more substituted or unsubstituted C3 to C30 heterocyclic groups including at least one selected from O, S, Se, Te, or Si; a fused ring of one or more substituted or unsubstituted C3 to C30 heterocyclic groups including at least one selected from O, S, Se, Te, or Si; a fused ring of one or more substituted or unsubstituted C3 to C30 heterocyclic groups and one or more substituted or unsubstituted phenylene group; a fused ring of one or more substituted or unsubstituted C3 to C30 heterocyclic groups and one or more substituted or unsubstituted naphthylene groups; a fused ring of one or more substituted or unsubstituted C3 to C30 heterocyclic groups and one or more substituted or unsubstituted anthracenylene groups; a fused ring of one or more substituted or unsubstituted C3 to C30 heterocyclic groups and one or more substituted or unsubstituted phenanthrenylene groups; or any combination thereof.

4. The copolymer of claim 1, wherein, in Chemical Formula 1 and Chemical Formula 2, D¹ and D² each independently comprise one of groups 1-1 to 1-13 listed in Group 1: 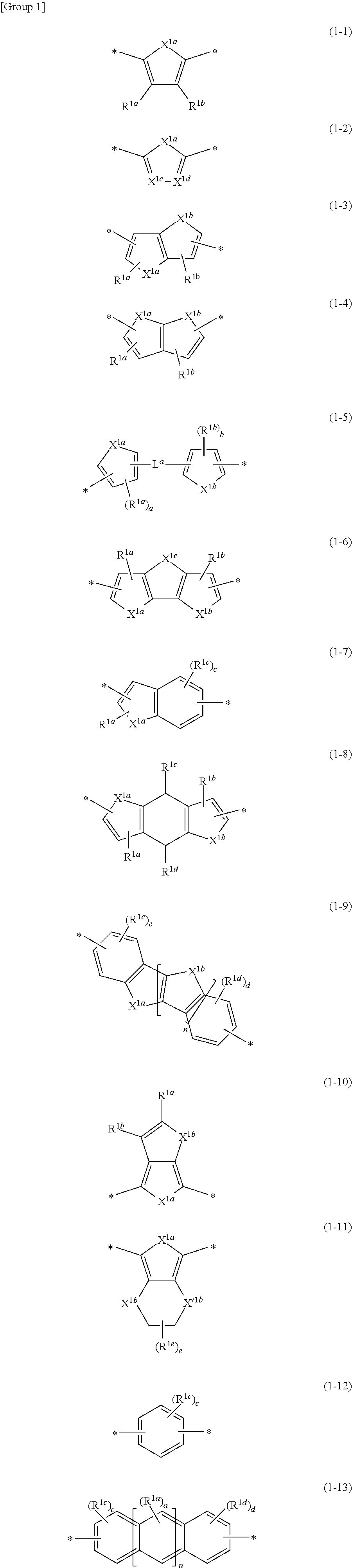
wherein, in Group 1,
X^{1a}, X^{1b}, and X′^{1b} are each independently O, S, Se, Te, or Si,
X^{1c} and X^{1d} are each independently N, CR^{x}, or SiR^{y},
X^{1e} is O, S, Se, Te, NR^{v}, CR^{w}R^{x}, or SiR^{y}R^{z},
R^{1a}, R^{1b}, R^{1c}, R^{1d}, R^{1e}, R^{x}, R^{y}, R^{v}, R^{w}, and R^{z} are each independently hydrogen, a substituted or unsubstituted C1 to C30 alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C3 to C30 cycloalkenyl group, a substituted or unsubstituted C1 to C30 alkoxy group, a substituted or unsubstituted C3 to C30 cycloheteroalkyl group, a substituted or unsubstituted C3 to C30 cycloheteroalkenyl group, a substituted or unsubstituted C6 to C30 aryl group, a substituted or unsubstituted C3 to C30 heterocyclic group, a halogen, or a cyano group,
L^{a} is a single bond or a substituted or unsubstituted C2 to C10 alkenylene group,
a and b are each independently 1 or 2,
c and d are each independently an integer of 1 to 3,
e is an integer of 1 to 4,
n is 0, 1, or 2, and
* is a linking point with Chemical Formula 1 or Chemical Formula 2.

5. The copolymer of claim 1, wherein, in Chemical Formula 1 and Chemical Formula 2,
L¹ to L⁴ each independently comprise a single bond; a substituted or unsubstituted C6 to C30 arylene group; a substituted or unsubstituted C3 to C30 divalent heterocyclic group including at least one selected from N, O, S, Se, Te, or Si; or any combination thereof,
L¹ and L² are each different from D¹, and
L³ and L⁴ are each different from D².

6. The copolymer of claim 1, wherein, in Chemical Formula 1 and Chemical Formula 2,
L¹ to L⁴ each independently comprise a single bond; a substituted or unsubstituted phenylene group; a substituted or unsubstituted naphthylene group; a substituted or unsubstituted C3 to C30 divalent heterocyclic group including at least one selected from O, S, Se, Te, or Si; or any combination thereof.

7. The copolymer of claim 1, wherein, in Chemical Formula 1 and Chemical Formula 2, L¹ to L⁴ each independently comprise one of groups 2-1 to 2-8 listed in Group 2: 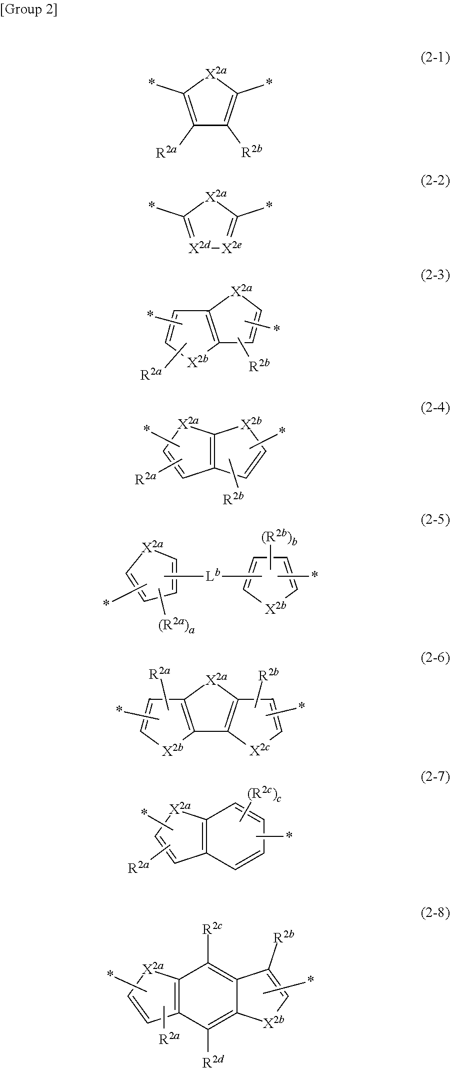
wherein, in Group 2,
X^{2a} to X^{2c} are each independently O, S, Se, or Te,
X^{2d} and X^{2e} are each independently N, CR^{x}, or SiR^{y},
R^{2a}, R^{2b}, R^{2c}, R^{2d}, R^{x}, and R^{y} are each independently hydrogen, a substituted or unsubstituted C1 to C30 alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C3 to C30 cycloalkenyl group, a substituted or unsubstituted C1 to C30 alkoxy group, a substituted or unsubstituted C3 to C30 cycloheteroalkyl group, a substituted or unsubstituted C3 to C30 cycloheteroalkenyl group, a substituted or unsubstituted C6 to C30 aryl group, a substituted or unsubstituted C3 to C30 heterocyclic group, a halogen, or a cyano group,
L^{b} is a single bond or a substituted or unsubstituted C2 to C10 alkenylene group,
a and b are each independently 1 or 2,
c is an integer of 1 to 3, and
* is a linking point with Chemical Formula 1 or Chemical Formula 2.

8. The copolymer of claim 1, wherein, in Chemical Formula 1 and Chemical Formula 2,
R³ is a substituted or unsubstituted C5 to C50 branched alkyl group, and
R¹ to R³ are each independently represented by Chemical Formula A: 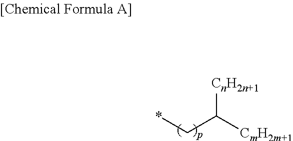
wherein, in Chemical Formula A,
n, m, and p are each independently an integer of 1 to 30, and
* is a linking point with Chemical Formula 1 or Chemical Formula 2,
wherein a sum of n, m, and p is less than or equal to 50.

9. The copolymer of claim 1, wherein, in Chemical Formula 2,
R⁴ is a substituted or unsubstituted C1 to C50 linear alkyl group, and
R⁴ is represented by Chemical Formula B: 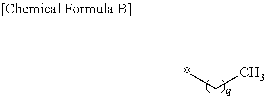
wherein, in Chemical Formula B,
q is an integer of 0 to 49, and
* is a linking point with Chemical Formula 2.

10. The copolymer of claim 1, wherein, in Chemical Formula 1 and Chemical Formula 2,
R¹ to R³ are a same C5 to C50 branched alkyl group, and
R⁴ is a substituted or unsubstituted C1 to C50 linear alkyl group.

11. The copolymer of claim 1, wherein
the first repeating unit and the second repeating unit are randomly arranged in the copolymer such that the copolymer includes a random arrangement of a first repeating unit quantity of units of the first repeating unit and a second repeating unit quantity of units of the second repeating unit, and
the second repeating unit quantity is smaller than the first repeating unit quantity in the copolymer.

12. The copolymer of claim 1, wherein the second repeating unit is included, in the copolymer, in an amount of about 5 mol % to about 30 mol % based on a total amount of the first repeating unit and the second repeating unit in the copolymer.

13. A copolymer, comprising:
a random arrangement of a first repeating unit quantity of units of a first repeating unit and a second repeating unit quantity of units of a second repeating unit,
wherein
the first repeating unit includes a first electron accepting moiety and a first electron donating moiety, the first electron accepting moiety having a symmetric structure,
the second repeating unit includes a second electron accepting moiety and a second electron donating moiety, the second electron accepting moiety having an asymmetric structure, and
the second repeating unit quantity is smaller than the first repeating unit quantity in the copolymer.

14. The copolymer of claim 13, wherein the second electron accepting moiety has a structure in which a main chain of a C6 to C30 aromatic ring or a C3 to C30 heterocyclic ring including at least one of nitrogen, a carbonyl group, a halogen, or a cyano group is substituted with a substituted or unsubstituted C1 to C50 linear alkyl group and a substituted or unsubstituted C5 to C50 branched alkyl group.

15. The copolymer of claim 14, wherein the first electron accepting moiety has a structure in which a main chain of a C6 to C30 aromatic ring or a C3 to C30 heterocyclic ring including at least one of nitrogen, a carbonyl group, a halogen, or a cyano group is substituted with two substituted or unsubstituted C5 to C50 branched alkyl groups positioned symmetrically to each other.

16. The copolymer of claim 13, wherein the first electron donating moiety and the second electron donating moiety each independently comprise a substituted or unsubstituted C6 to C30 arylene group; a substituted or unsubstituted C3 to C30 divalent heterocyclic group including at least one selected from O, S, Se, Te, or Si; a fused ring thereof; or any combination thereof.

17. The copolymer of claim 13, wherein the second repeating unit is included in the copolymer in an amount of about 5 mol % to 30 mol % based on a total amount of the first repeating unit and the second repeating unit in the copolymer.

18. An electronic device comprising the copolymer of claim 1.

19. A thin film transistor, comprising:
a gate electrode;
an organic semiconductor overlapped with the gate electrode, the organic semiconductor including the copolymer of claim 1; and
a source electrode and a drain electrode, the source electrode and the drain electrode electrically connected to the organic semiconductor.

20. An electronic device comprising the thin film transistor of claim 19.
